(19) United States
(12) Patent Application Publication
(10) Pub. No.: US 2026/0143919 A1
(43) Pub. Date: May 21, 2026

(54) DISPLAY PANEL, METHOD OF MANUFACTURING THE DISPLAY PANEL, AND ELECTRONIC APPARATUS INCLUDING THE DISPLAY PANEL

(71) Applicant: Samsung Display Co., Ltd., Yongin-si, Gyeonggi-do (KR)

(72) Inventors: Youngkwang Lee, Yongin-si (KR); Euigyu Kim, Yongin-si (KR); Sangmin Yi, Yongin-si (KR); Jongdae Lee, Yongin-si (KR); Jongsung Park, Yongin-si (KR)

(73) Assignee: Samsung Display Co., Ltd., Yongin-si, Gyeonggi-do (KR)

(21) Appl. No.: 19/279,479

(22) Filed: Jul. 24, 2025

(30) Foreign Application Priority Data
Nov. 19, 2024 (KR) 10-2024-0165509

(51) Int. Cl. H10K 59/122; H10K 59/12; H10K 59/35

(52) U.S. Cl. CPC H10K 59/122; H10K 59/1201; H10K 59/35

(57) ABSTRACT

A display panel, a method of manufacturing the display panel, and an electronic apparatus including the display panel. The display panel may include a first sub-pixel, a second sub-pixel, and a third sub-pixel that emits light of different colors, wherein, the first sub-pixel and the third sub-pixel are arranged in a first direction in a plan view, and the first sub-pixel and the second sub-pixel are arranged in a second direction perpendicular to the first direction in a plan view, and a separation distance between the first sub-pixel and the third sub-pixel is different from a separation distance between the first sub-pixel and the second sub-pixel.

### CROSS-REFERENCE TO RELATED APPLICATION(S)

This application claims priority under 35 U.S.C. § 119 to and the benefits of Korean Patent Application No. 10-2024-0165509 filed on Nov. 19, 2024, in the Korean Intellectual Property Office, the entire contents of which is incorporated herein by reference.

### BACKGROUND

### 1. Technical Field

One or more embodiments relate to a display panel, a method of manufacturing the display panel, and an electronic apparatus including the display panel.

### 2. Description of the Related Art

Recently, electronic apparatuses have been widely used. Electronic apparatuses are variously used as mobile electronic apparatuses and fixed electronic apparatuses. To support various functions, an electronic apparatus includes a display panel which may provide visual information such as images to users.

A display panel is an apparatus configured to visually display data and is formed by depositing various layers such as an organic layer, a metal layer, and the like. A deposition material may be deposited to form multiple layers of a display panel. For example, the deposition material from a deposition source may be sprayed and deposited on a substrate through a mask assembly.

### SUMMARY

One or more embodiments include a display panel with reduced spot defects caused by a brightness difference, a method of manufacturing the display panel, and an electronic apparatus including the display panel. However, such a technical objective is just an example, and the disclosure is not limited thereto.

Additional aspects will be set forth in part in the description which follows and, in part, will be apparent from the description, or may be learned by practice of the presented embodiments of the disclosure.

According to one or more embodiments, a display panel may include a first sub-pixel, a second sub-pixel, and a third sub-pixel that emits light of different colors, wherein the first sub-pixel and the third sub-pixel may be arranged in a first direction in a plan view, and the first sub-pixel and the second sub-pixel may be arranged in a second direction perpendicular to the first direction in a plan view, and a separation distance between the first sub-pixel and the third sub-pixel may be different from a separation distance between the first sub-pixel and the second sub-pixel.

In an embodiment, the separation distance between the first sub-pixel and the third sub-pixel in a plan view may be less than the separation distance between the first sub-pixel and the second sub-pixel.

In an embodiment, the separation distance between the first sub-pixel and the second sub-pixel in a plan view may be in a range of about 15.5 μm to about 32 μm.

In an embodiment, each of the first sub-pixel, the second sub-pixel, and the third sub-pixel may have a rectangular shape in a plan view with a first side extending in the first direction and a second side extending in the second direction.

In an embodiment, a length of the first side of the first sub-pixel may be substantially equal to a length of the first side of the second sub-pixel, and a length of the second side of the first sub-pixel may be different from a length of the second side of the second sub-pixel.

In an embodiment, a length of the first side of the first sub-pixel may be greater than a length of the second side of the first sub-pixel, a length of the first side of the second sub-pixel may be greater than a length of the second side of the second sub-pixel, and a length of the first side of the third sub-pixel may be less than a length of the second side of the third sub-pixel.

In an embodiment, the third sub-pixel may correspond to the first sub-pixel and the second sub-pixel in the first direction.

In an embodiment, an area of the first sub-pixel may be greater than an area of the second sub-pixel, and an area of the third sub-pixel may be greater than an area of the first sub-pixel.

In an embodiment, each of the first sub-pixel, the second sub-pixel, and the third sub-pixel may include a sub-pixel electrode, an emission layer disposed on the sub-pixel electrode, and an opposite electrode disposed on the emission layer, each of the first sub-pixel, the second sub-pixel, and the third sub-pixel may be defined by an opening in a bank layer disposed on the sub-pixel electrode, the bank layer may overlap edge portions of the sub-pixel electrode, and the emission layer of the first sub-pixel may have a uniform thickness in a region in which the emission layer is in contact with the sub-pixel electrode exposed by the opening of the bank layer.

According to one or more embodiments, a method of manufacturing a display panel may include providing the display panel that includes a first sub-pixel, a second sub-pixel, and a third sub-pixel, disposing a substrate and a mask assembly inside a chamber, the mask assembly may include a mask sheet, and spraying a deposition material onto the substrate while moving a deposition source in a first direction relative to the substrate, wherein, the first sub-pixel and the third sub-pixel may be arranged in the first direction in a plan view, and the first sub-pixel and the second sub-pixel may be arranged in a second direction perpendicular to the first direction in a plan view, and a separation distance between the first sub-pixel and the third sub-pixel in a plan view may be different from a separation distance between the first sub-pixel and the second sub-pixel.

In an embodiment, the deposition source may include a plurality of nozzles arranged in the second direction, and at least some of the plurality of nozzles may be tilted at a preset angle.

In an embodiment, each of the first sub-pixel, the second sub-pixel, and the third sub-pixel may include a sub-pixel electrode, an emission layer, and an opposite electrode, wherein the spraying of the deposition material may include forming the emission layer of each of the first sub-pixel, the second sub-pixel, and the third sub-pixel.

In an embodiment, the separation distance between the first sub-pixel and the third sub-pixel in a plan view may be less than the separation distance between the first sub-pixel and the second sub-pixel.

In an embodiment, the separation distance between the first sub-pixel and the second sub-pixel in a plan view may be in a range of about 15.5 μm to about 32 μm.

In an embodiment, each of the first sub-pixel, the second sub-pixel, and the third sub-pixel may have a rectangular shape in a plan view with a first side extending in the first direction, and a second side extending in the second direction.

In an embodiment, a length of the first side of the first sub-pixel may be substantially equal to a length of the first side of the second sub-pixel, and a length of the second side of the first sub-pixel may be different from a length of the second side of the second sub-pixel.

In an embodiment, a length of the first side of the first sub-pixel may be greater than a length of the second side of the first sub-pixel, a length of the first side of the second sub-pixel may be greater than a length of the second side of the second sub-pixel, and a length of the first side of the third sub-pixel may be less than a length of the second side of the third sub-pixel.

In an embodiment, the third sub-pixel may correspond to the first sub-pixel and the second sub-pixel in the first direction.

According to one or more embodiments, a display panel may be manufactured by the method of manufacturing of the display panel.

According to one or more embodiments, an electronic apparatus may include the display panel manufactured by the method of manufacturing of the display panel, and a lower cover may form an exterior of the electronic apparatus and may include an opening exposing a portion of the display panel.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a schematic cross-sectional view of an apparatus for manufacturing a display panel according to an embodiment;

FIG. 2 is a schematic perspective view of a mask assembly according to an embodiment;

FIG. 3A is a schematic plan view of a mask sheet according to an embodiment;

FIG. 3B is a schematic cross-sectional view of the mask sheet taken along line III-III′ of FIG. 3A according to an embodiment;

FIG. 4A is a schematic cross-sectional view of an apparatus for manufacturing a display panel according to an embodiment;

FIG. 4B is an enlarged schematic cross-sectional view of a region IV of FIG. 4A according to an embodiment;

FIG. 5 is a schematic perspective view of a deposition source according to an embodiment;

FIG. 6A is a schematic cross-sectional view of the deposition source taken along line I-I′ of FIG. 5 according to an embodiment;

FIG. 6B is a schematic cross-sectional view of the deposition source taken along line II-II′ of FIG. 5 according to an embodiment;

FIG. 7 is a schematic perspective view of an electronic apparatus including a display panel manufactured by using an apparatus for manufacturing a display panel according to an embodiment;

FIG. 8 is a schematic exploded perspective view of the electronic apparatus of FIG. 7;

FIG. 9 is a schematic block diagram of the electronic apparatus of FIG. 7;

FIG. 10 is a schematic perspective view of a display panel according to an embodiment;

FIG. 11 is a schematic cross-sectional view of a portion of a display area of a display panel according to an embodiment;

FIG. 12 is a schematic plan view of a sub-pixel arrangement of a display panel according to an embodiment;

FIG. 13 is a schematic view showing an arrangement of sub-pixels of a display panel according to an embodiment;

FIG. 14 is a schematic view showing an arrangement of sub-pixels of a display panel according to a comparative example; and

FIG. 15 is a schematic cross-sectional view of the display panel taken along line VI-VI′ of FIG. 13 according to an embodiment.

### DETAILED DESCRIPTION OF THE EMBODIMENTS

In the following description, for the purposes of explanation, numerous specific details are set forth in order to provide a thorough understanding of various embodiments or implementations of the disclosure. As used herein “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

Unless otherwise specified, the illustrated embodiments are to be understood as providing features of the disclosure. Therefore, unless otherwise specified, the features, components, modules, layers, films, panels, regions, and/or aspects, etc., (hereinafter individually or collectively referred to as “elements”), of the various embodiments may be otherwise combined, separated, interchanged, and/or redisposed without departing from the disclosure.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals and/or reference characters denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the X-axis, the Y-axis, and the Z-axis are not limited to three axes of a rectangular coordinate system, such as the x, y, and z axes, and may be interpreted in a broader sense. For example, the X-axis, the Y-axis, and the Z-axis may be perpendicular to one another, or may be different directions that are not perpendicular to one another.

For the purposes of this disclosure, “at least one of A and B” may be construed as A only, B only, or any combination of A and B. Also, “at least one of X, Y, and Z” and “at least one selected from the group consisting of X, Y, and Z” may be construed as X only, Y only, Z only, or any combination of two or more of X, Y, and Z. As used herein, the term “and/or” includes any and all combinations of one or more of the associated listed items.

Although the terms “first,” “second,” etc., may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may otherwise be oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As customary in the field, some embodiments are described and illustrated in the accompanying drawings in terms of functional blocks, parts, and/or modules. Those skilled in the art will appreciate that these blocks, parts, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, parts, and/or modules being implemented by microprocessors or other similar hardware, they may be programmed and controlled using software (e.g., microcode) to perform various functions discussed herein and may optionally be driven by firmware and/or software. It is also contemplated that each block, part, and/or module may be implemented by dedicated hardware, or as a combination of dedicated hardware to perform some functions and a processor (e.g., one or more programmed microprocessors and associated circuitry) to perform other functions. Also, each block, part, and/or module of some embodiments may be physically separated into two or more interacting and discrete blocks, parts, and/or modules without departing from the scope of the disclosure. Further, the blocks, parts, and/or modules of some embodiments may be physically combined into more complex blocks, parts, and/or modules without departing from the scope of the disclosure.

Unless otherwise defined or implied herein, all terms (including technical and scientific terms) used herein have the same meaning as commonly understood by those skilled in the art to which this disclosure pertains. It will be further understood that terms, such as those defined in commonly used dictionaries, should be interpreted as having a meaning that is consistent with their meaning in the context of the relevant art and the disclosure, and should not be interpreted in an ideal or excessively formal sense unless clearly defined herein.

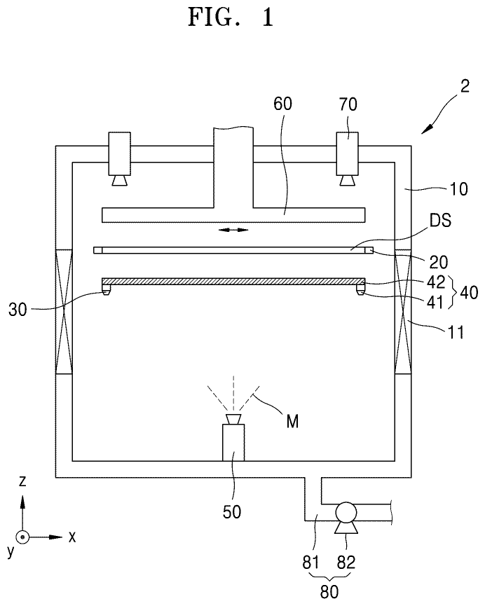

FIG. 1 is a schematic cross-sectional view of an apparatus 2 for manufacturing a display panel according to an embodiment.

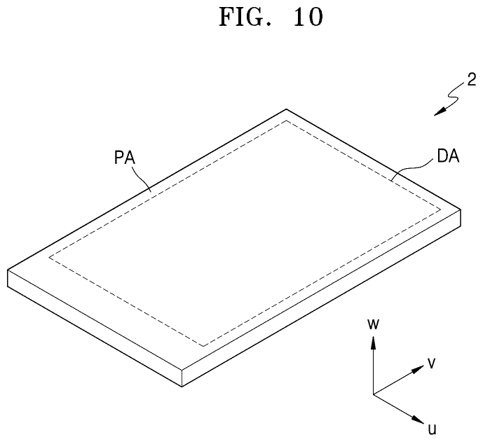

Referring to FIG. 1, the apparatus 2 for manufacturing a display panel according to an embodiment may be used to manufacture a display panel 1 (see FIG. 10) described below.

The apparatus 2 for manufacturing a display panel may include a chamber 10, a first supporter 20, a second supporter 30, a mask assembly 40, a deposition source 50, a magnetic force portion 60, a vision portion 70, and a pressure adjustor 80.

A space may be formed inside the chamber 10. A display substrate DS and the mask assembly 40 may be inserted in the space. A portion of the chamber 10 may include an opening. A gate valve 11 may be installed in an opening portion of the chamber 10. The opening portion of the chamber 10 may be opened or closed according to an operation of the gate valve 11.

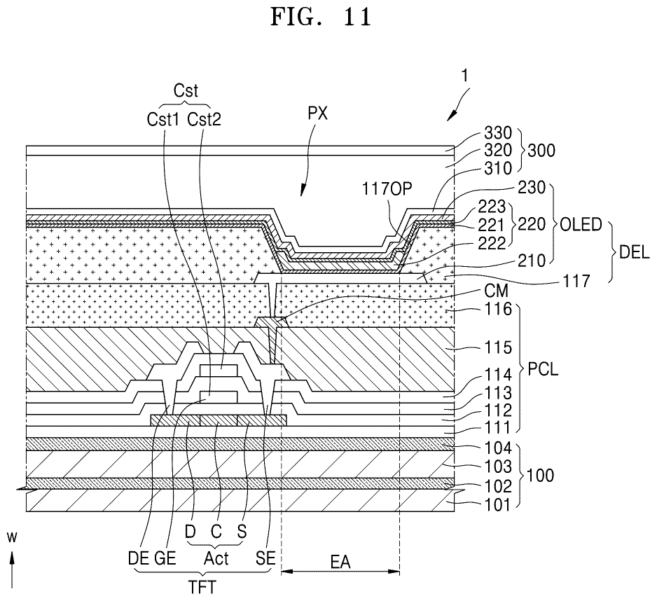

The display substrate DS may include at least one of an organic layer, an inorganic layer, and a metal layer deposited on a substrate 100 (see FIG. 11) during the manufacture of the display panel. The display substrate DS may include the substrate 100 (see FIG. 11) on which any of the organic layer, the inorganic layer, and the metal layer is not yet deposited.

The first supporter 20 may be configured to support the display substrate DS. The first supporter 20 may be in the form of a plate fixed inside the chamber 10. In an embodiment, the first supporter 20 may be in the form of a shuttle on which the display substrate DS sits and which is linearly movable inside the chamber 10. In an embodiment, the first supporter 20 may include an electrostatic chuck or an adhesive chuck disposed in the chamber 10 to be fixed or movable inside the chamber 10.

The second supporter 30 may be configured to support the mask assembly 40. The second supporter 30 may be disposed inside the chamber 10. The second supporter 30 may fine-adjust the position of the mask assembly 40. The second supporter 30 may include a driver, an alignment part, or the like separately to move the mask assembly 40 in different directions.

In an embodiment, the second supporter 30 may be a shuttle form. The mask assembly 40 may sit on the second supporter 30. The second supporter 30 may be configured to transfer the mask assembly 40. As an example, the second supporter 30 may move to the outside of the chamber 10, and after the mask assembly 40 sits on the second supporter 30, the second supporter 30 may enter the chamber 10 from the outside of the chamber 10.

The first supporter 20 and the second supporter 30 may be integral with each other. The first supporter 20 and the second supporter 30 may include a movable shuttle. The first supporter 20 and the second supporter 30 may include a structure configured to fix the mask assembly 40 to the display substrate DS with the display substrate DS sitting on the mask assembly 40, and be configured to linearly move the display substrate DS and the mask assembly 40 simultaneously.

Hereinafter, for convenience of description, a form in which the first supporter 20 and the second supporter 30 are formed to be discriminated from each other and disposed in different positions, and a form in which the first supporter 20 and the second supporter 30 are disposed inside the chamber 10, are described.

The mask assembly 40 may be disposed inside the chamber 10 to face the display substrate DS. A deposition material M may pass through the mask assembly 40 and be deposited on the display substrate DS.

The deposition source 50 may be disposed to face the mask assembly 40 and configured to supply the deposition material M such that the deposition material M passes through a deposition region of the mask assembly 40 and is deposited on the display substrate DS. The deposition source 50 may evaporate or sublimate the deposition material M by applying heat to the deposition material M. The deposition source 50 may be disposed to be fixed inside the chamber 10, or disposed inside the chamber 10 to be linearly movable in a direction (e.g., single direction).

The magnetic force portion 60 may be disposed inside the chamber 10 to face the display substrate DS and/or the mask assembly 40. The magnetic force portion 60 may apply magnetic force to the mask assembly 40 to press the mask assembly 40 toward the display substrate DS. Particularly, the magnetic force portion 60 may not only prevent sagging of a mask sheet 42, but may also allow the mask sheet 42 to be adjacent to the display substrate DS. The magnetic force portion 60 may maintain a uniform interval between the mask sheet 42 and the display substrate DS.

The vision portion 70 may be disposed in the chamber 10 and may capture the positions of the display substrate DS and the mask assembly 40. The vision portion 70 may include a camera capturing the display substrate DS and the mask assembly 40. The positions of the display substrate DS and the mask assembly 40 may be determined, and the transformation of the mask assembly 40 may be determined based on the images captured by the vision portion 70. The first supporter 20 may be configured to fine-adjust the position of the display substrate DS, or the second supporter 30 may be configured to fine-adjust the position of the mask assembly 40 based on the captured images.

The pressure adjustor 80 may be connected to the chamber 10 and may adjust the inner pressure of the chamber 10. As an example, the pressure adjustor 80 may be configured to adjust the inner pressure of the chamber 10 to be equal (or substantially equal) or similar to the atmospheric pressure. The pressure adjustor 80 may be configured to adjust the inner pressure of the chamber 10 to be equal or similar to a vacuum state.

The pressure adjustor 80 may include a connection pipe 81 and a pump 82, and the connection pipe 81 may be connected to the chamber 10, and the pump 82 is installed to the connection pipe 81. External air may be introduced through the connection pipe 81 or a gas inside the chamber 10 may be guided to the outside through the connection pipe 81 according to an operation of the pump 82.

A method of manufacturing a display panel by using the apparatus 2 for manufacturing a display panel, is described. First, the display substrate DS may be prepared.

The pressure adjustor 80 may maintain the inside of the chamber 10 at a state equal or similar to the atmospheric pressure. The gate valve 11 may operate to open the opening portion of the chamber 10.

Then, the display substrate DS may be loaded into the inside of the chamber 10 from the outside. The display substrate DS may be loaded into the chamber 10 in various methods. As an example, the display substrate DS may be loaded into the inside of the chamber 10 from the outside of the chamber 10 by a robot arm and the like disposed outside the chamber 10. In an embodiment, in the case where the first supporter 20 is formed in a shuttle form, the first supporter 20 may be carried from the inside of the chamber 10 to the outside of the chamber 10, then, the display substrate DS may sit on the first supporter 20 by a separate robot arm and the like disposed outside the chamber 10, and the first supporter 20 may be loaded into the inside of the chamber 10 from the outside of the chamber 10.

The mask assembly 40 may be disposed inside the chamber 10 as described above. In an embodiment, in the equal or similar manner to the display substrate DS, the mask assembly 40 may be loaded into the inside of the chamber 10 from the outside of the chamber 10.

In case that the display substrate DS is loaded into the inside of the chamber 10, the display substrate DS may sit on the first supporter 20. The vision portion 70 may be configured to capture the positions of the display substrate DS and the mask assembly 40. The positions of the display substrate DS and the mask assembly 40, may be determined based on images captured by the vision portion 70. The apparatus 2 for manufacturing a display panel may include a separate controller (not shown) to determine the positions of the display substrate DS and the mask assembly 40.

In case that the determination of the positions of the display substrate DS and the mask assembly 40 is complete, the second supporter 30 may fine-adjust the position of the mask assembly 40.

Then, the deposition source 50 operates to supply the deposition material M toward the mask assembly 40, and the deposition material M passing through an opening of the mask sheet 42 may be deposited on the display substrate DS. The deposition source 50 may move in parallel to the display substrate DS and the mask assembly 40, or the display substrate DS and the mask assembly 40 may move in parallel to the deposition source 50. For example, the deposition source 50 may move relative to the display substrate DS and the mask assembly 40. The pump 82 may maintain the pressure of the chamber 10 at a state equal or similar to vacuum by sucking in the gas inside the chamber 10 and discharging the gas to the outside.

The deposition material M supplied from the deposition source 50 may pass through the mask assembly 40, be deposited on the display substrate DS, and thus form at least one of multiple layers, for example, an organic layer, an inorganic layer, and a metal layer stacked on each other and on the display panel described below.

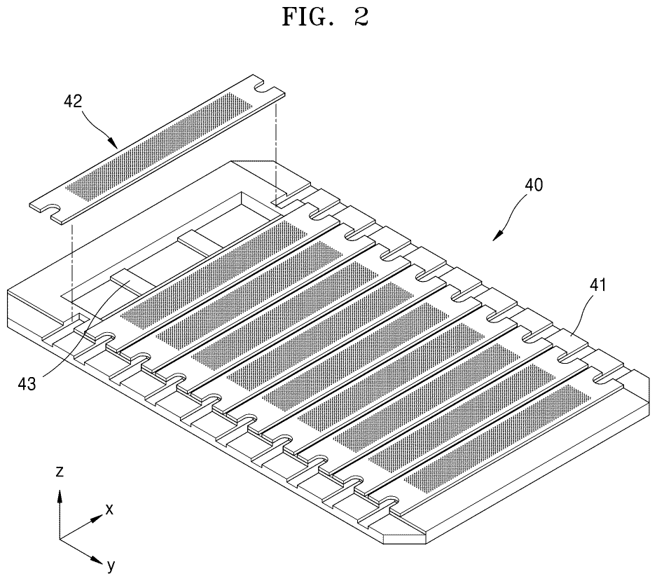

FIG. 2 is a schematic perspective view of the mask assembly 40 according to an embodiment.

Referring to FIG. 2, the mask assembly 40 may include a mask frame 41, the mask sheet 42, and a support frame 43.

The mask frame 41 may be formed by multiple frames connected to each other and may include an opening therein. The mask frame 41 may include an opening (e.g., single opening) or may include multiple openings discriminated from each other. The mask frame 41 may include a grid shape such as a window frame. Hereinafter, for convenience of description, a case where the mask frame 41 includes an opening (e.g., single opening) in the center thereof is described.

In an embodiment, the mask frame 41 may be a quadrangular frame. However, the shape of the mask frame 41 is not necessarily limited thereto and may have various polygonal shapes.

The mask sheet 42 may be tensioned and installed to the mask frame 41. The mask sheet 42 may include an opening through which the deposition material passes. A mask sheet (e.g., single mask sheet) 42 may be provided or multiple mask sheets 42 may be provided. In the case where a mask sheet (e.g., single mask sheet) 42 is provided, the mask sheet 42 may be disposed on the mask frame 41 to shield the opening of the mask frame 41. In an embodiment, in the case where multiple mask sheets 42 are provided, the mask sheets 42 may be disposed to be adjacent to each other along a side (e.g., single side) of the mask frame 41 and may shield the opening of the mask frame 41.

In the case where multiple mask sheets 42 are provided, the mask sheets 42 may be disposed to be parallel to each other on the mask frame 41. As an example, each of the mask sheets 42 may have a shape extending long in an x direction. The mask sheets 42 may be arranged (or disposed) side-by-side in a y direction intersecting a lengthwise direction. Two opposite ends of the mask sheet 42 may be fixed to the mask frame 41 by welding, for example.

The support frame 43 may be disposed on the opening of the mask frame 41, may shield a space between adjacent mask sheets 42, or may extend in a second direction (e.g., y direction) intersecting the lengthwise direction (e.g., x direction) of the mask sheet 42. Recesses may be disposed in the mask frame 41 to receive two opposite ends of the support frame 43. However, this is just an example, and separate recesses may not be disposed in the mask frame 41, and the support frame 43 may be disposed on the mask frame 41. The support frame 43 may support the mask sheet 42 in the opening of the mask frame 41 to prevent sagging of the mask sheet 42.

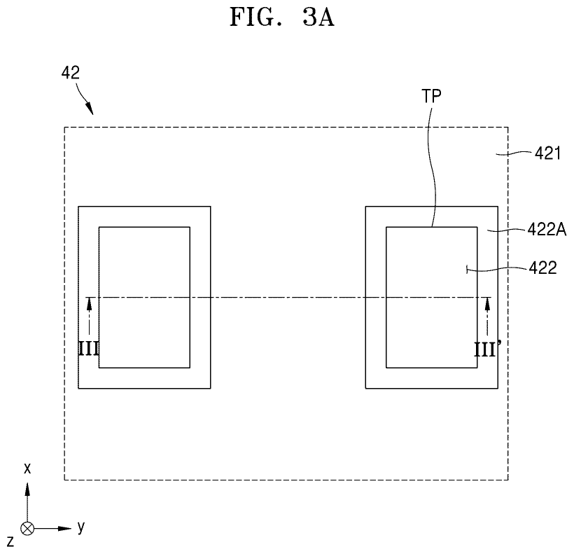

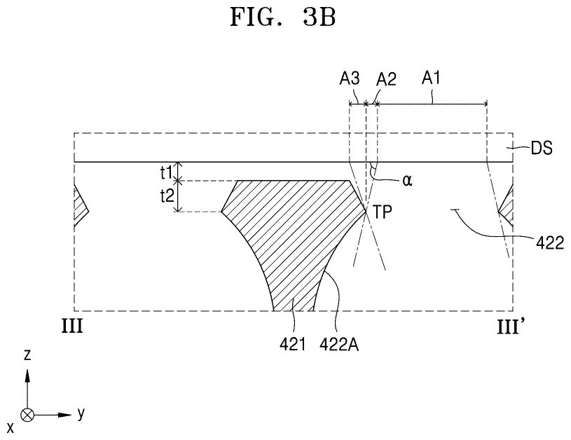

FIG. 3A is a schematic plan view of the mask sheet 42 according to an embodiment. FIG. 3B is a schematic cross-sectional view of the mask sheet 42, taken along line III-III′ of FIG. 3A according to an embodiment and shows the mask sheet 42 and a corresponding portion of the display substrate DS.

Referring to FIGS. 3A and 3B, the mask sheet 42 may include a body portion 421 and an opening 422.

The body portion 421 may form an exterior of the mask sheet 42. The body portion 421 may be formed in a shape of a thin plate. As an example, the body portion 421 may have a rectangular shape as shown in FIG. 2. However, the shape of the body portion 421 shown in FIG. 2 is just an example, and the shape of the body portion 421 may be variously modified depending on the purpose and use thereof.

The opening 422 may be disposed in the body portion 421 to transmit the deposition material. The opening 422 may be formed to pass through the body portion 421 in a thickness direction (e.g., −z direction) from a surface (e.g., single surface facing +z direction) of the body portion 421. At least one opening 422 may be provided. A planar shape of at least one of the openings 422 may be quadrangular. As an example, a planar shape of each of the openings 422 may be quadrangular. Because the planar shape of the opening 422 is quadrangular, a region in which the deposition material is deposited on the display substrate DS may be quadrangular. However, the disclosure is not necessarily limited thereto. In an embodiment, the planar shape of the opening 422 may be a circular shape, an elliptical shape, or a polygon shape such as a pentagon.

In a cross-section parallel to the thickness direction (e.g., z direction) of the mask sheet 42, an inner surface 422A of the opening 422 may include a sloped surface. As an example, a sloped surface (e.g., single sloped surface) included in the inner surface 422A of the opening 422 may be inclined to face the deposition source 50. In a plan view as shown in FIG. 3A, in the case where the planar shape of the opening 422 is quadrangular, a planar shape of the sloped surface may be also quadrangular.

A cross-sectional shape of the opening 422 may change depending on a method of forming the opening 422. As an example, the opening 422 may be formed by etching solution, a laser beam, or the like. In an embodiment, as shown in FIG. 3B, in the case where the opening 422 is formed by an etching solution, the inner surface 422A of the opening 422 may include a curved surface. However, the shape of the opening 422 shown in FIG. 3B is just an example, and the cross-sectional shape of the opening 422 is not necessarily limited thereto. Hereinafter, description is made on the assumption that the opening 422 has a cross-sectional structure of FIG. 3B.

Referring to FIG. 3B, the inner surface 422A of the opening 422 may include an inclined portion to face the display substrate DS and an inclined portion to face the deposition source 50 (see FIG. 1). As an example, the inclined portion to face the deposition source 50 may include a curved surface. A portion where the two inclined portions meet each other may correspond to a protrusion TP. Here, the protrusion TP of the body portion 421 may be a portion protruding in a direction facing the center of the opening 422. A planar shape of the protrusion TP may be the same as a planar shape of the opening 422.

As described above, the deposition material sprayed from the deposition source 50 and passing through the opening 422 of the mask sheet 42 may be deposited on the display substrate DS. The deposition material sprayed from the deposition source 50 may be incident to the display substrate DS at a preset incident angle.

A region of the display substrate DS corresponding to the opening 422 may be a region that needs deposition, and a region of the display substrate DS corresponding to the body portion 421 may be a region that does not need deposition. A region where the deposition material may not swiftly reach due to being covered (or overlapped) by the body portion 421 may be formed in the region corresponding to the opening 422. For example, during a process of supplying the deposition material from the deposition source 50 to the display substrate DS, a region where the deposition material may not pass through the opening 422 due to the body portion 421, for example, the protrusion TP of the body portion 421 may be formed. A region where the deposition material additionally reaches due to the inclined portion (e.g., inclined portion to face the display substrate DS) of the inner surface 422A of the opening 422, may be formed in a region of the mask sheet 42 corresponding to the body portion 421.

Referring to FIG. 3B, a first region A1 may be a region where the deposition material is deposited to a normal thickness, and a second region A2 and a third region A3 may be regions (hereinafter, referred to as ‘shadow regions’) where the deposition material is not deposited to the normal thickness. Here, the shadow region may include an outer shadow region and an inner shadow region. The outer shadow region denotes a region where the deposition material is deposited among regions that need deposition, and the inner shadow region denotes a region where only a portion of the deposition material is deposited among regions that do not need deposition. The second region A2 may be the inner shadow region, and the third region A3 may be the outer shadow region.

The areas of the second region A2 and the third region A3 may be changed by the cross-sectional shape of the mask sheet 42, for example, the shape of the protrusion TP of the body portion 421 and/or the shape of the inner surface 422A of the opening 422. The areas of the second region A2 and the third region A3 may be changed by not only the cross-sectional shape of the mask sheet 42 but also by a separation distance t1 between the mask sheet 42 and the display substrate DS and/or a minimum incident angle α of the deposition material incident to the display substrate DS. As an example, as the separation distance t1 between the mask sheet 42 and the display substrate DS increases, the areas of the second region A2 and the third region A3 may increase. As the minimum incident angle α of the deposition material incident to the display substrate DS increases, the areas of the second region A2 and the third region A3 may be reduced.

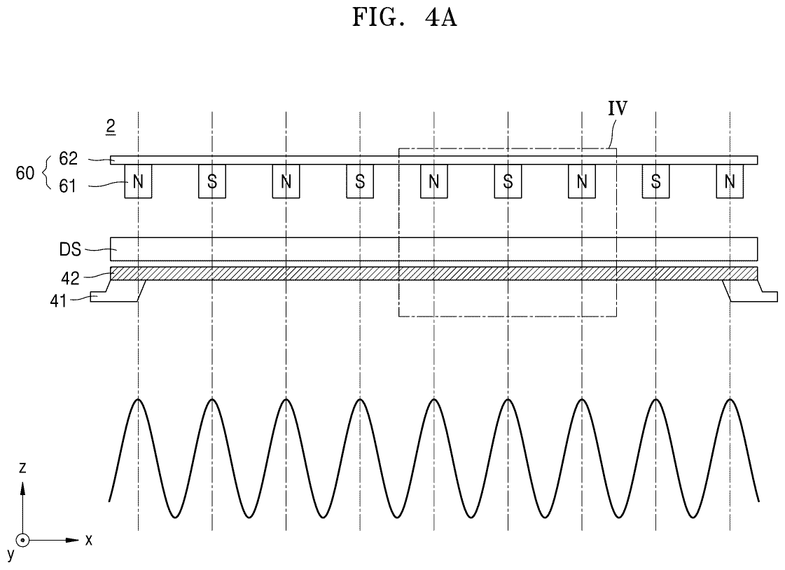

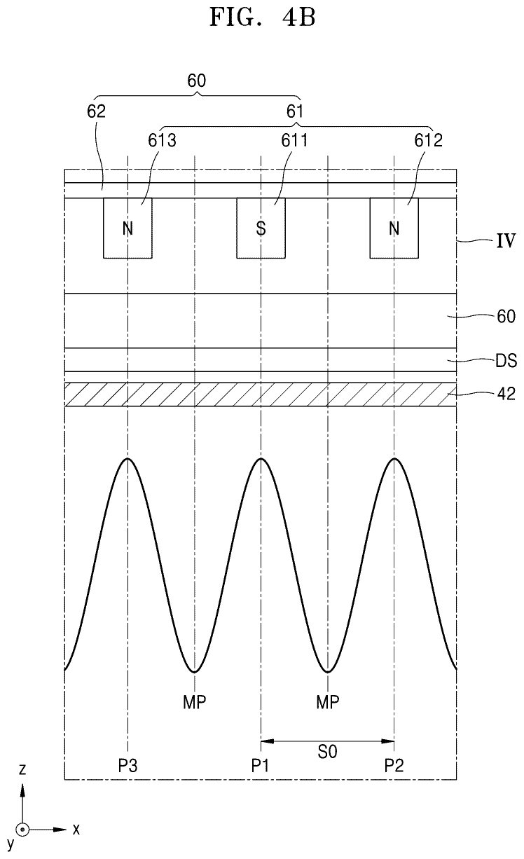

FIG. 4A is a schematic cross-sectional view of an apparatus for manufacturing a display panel according to an embodiment, and FIG. 4B is an enlarged schematic cross-sectional view of a region IV of FIG. 4A according to an embodiment.

For convenience of description, FIGS. 4A and 4B show the mask assembly 40 and the magnetic force portion 60 with the support frame 43 omitted. FIGS. 4A and 4B shows magnetic force acting on the mask sheet 42.

The magnetic force portion 60 may be disposed to face the display substrate DS. As an example, the magnetic force portion 60 may be disposed to face a surface (e.g., single surface facing a +z direction) of the display substrate DS.

The display substrate DS may be located between the magnetic force portion 60 and the mask assembly 40. The mask sheet 42 of the mask assembly 40 may be disposed on the mask frame 41. The mask sheet 42 may be disposed to face another surface (e.g., surface facing a −z direction) of the display substrate DS. The display substrate DS may be disposed adjacent to the mask sheet 42. The magnetic force portion 60 may apply magnetic force such that the mask sheet 42 is in contact with or located close to the display substrate DS.

The magnetic force portion 60 may include a magnet 61 and a support plate 62. The magnet 61 may be provided in plural. As an example, although nine magnets 61 may be provided as shown in FIG. 4A, the embodiment is not limited thereto. The number of magnets 61 may be changed depending on the display substrate DS and the size of the mask sheet 42 corresponding thereto.

The magnets 61 may be accommodated in the support plate 62. For example, the support plate 62 may be a plate supporting the magnets 61. In an embodiment, the magnets 61 supported by the support plate 62 may be disposed on a plane substantially parallel to the mask sheet 42. Each of the magnets 61 may extend in a direction. The magnets 61 may be arranged apart from each other in a direction (e.g., x direction) perpendicular to the lengthwise direction (e.g., y direction) of the magnet 61. Separation distances S0 between the magnets 61 may be equal to each other.

A lengthwise direction of the magnet 61 may cross a lengthwise direction of the mask sheet 42. A direction in which the magnets 61 are arranged may intersect a direction in which the mask sheets 42 are arranged. In an embodiment, the lengthwise direction of the magnet 61 and the arrangement direction of the mask sheets 42 may be the same in the y direction, and the arrangement direction of the magnets 61 and the lengthwise direction of the mask sheet 42 may be the same in the x direction.

In an embodiment, the magnets 61 may include magnets 61 in which a polarity of a side facing the mask sheet 42 has an N pole, and magnets 61 in which a polarity of a side facing the mask sheet 42 has an S pole, and the magnets 61 having the N pole and the magnets 61 having the S pole may be alternately disposed. Magnetic force applied to the mask sheets 42 may follow a sine curve (or cosine curve) along the lengthwise direction (e.g., x direction) of the mask sheets 42.

Referring to FIG. 4B, the magnets 61 may include a first magnet 611, a second magnet 612, and a third magnet 613. The second magnet 612 may be disposed adjacent to the first magnet 611 and on a side (e.g., in the x direction) of the first magnet 611, and the third magnet 613 may be disposed adjacent to the first magnet 611 and on the opposite side (e.g., in a −x direction) that faces away from the second magnet 612.

As described above, magnetic force that follows a sine curve (or cosine curve) may be applied to the mask sheet 42 in the lengthwise direction (e.g., x direction). Specifically, maximum magnetic force may be applied to points of the mask sheet 42 corresponding to the magnets 61 in the lengthwise direction, for example, a first point P1 below the first magnet 611, a second point P2 below the second magnet 612, and a third point P3 below the third magnet 613. Minimum magnetic force may be applied to points of the mask sheet 42 that do not correspond to the magnets 61 in the lengthwise direction, for example, an intermediate point MP between the first point P1 and the second point P2, and an intermediate point MP between the first point P1 and the third point P3. Accordingly, magnetic force applied in the lengthwise direction (e.g., x direction) of the mask sheet 42 may represent a sine curve whose period is a distance S0 between the first magnet 611 and the second magnet 612, in other words, the distance S0 between the first point P1 and the second point P2.

Generally, in the case where the magnetic force portion 60 is fixed at a stationary position, the adhesion between the mask sheet 42 and the display substrate DS may not be good at an intermediate point MP of the mask sheet 42 where the minimum magnetic force is applied. A separation between the mask sheet 42 and the display substrate DS may occur at the intermediate point MP, or the separation distance t1 may increase.

As described with reference to FIG. 3B, in case that the separation distance t1 between the mask sheet 42 and the display substrate DS increases, an inner shadow region (e.g., region A2 of FIG. 3B) may increase. For example, the inner shadow region may increase at the intermediate point MP compared to the first point P1 to the third point P3. Accordingly, the deposition material of the emission layer and the like may not be properly deposited at the intermediate point MP. Due to this magnetic force pattern, spot defects due to periodic brightness differences may occur on the display panel.

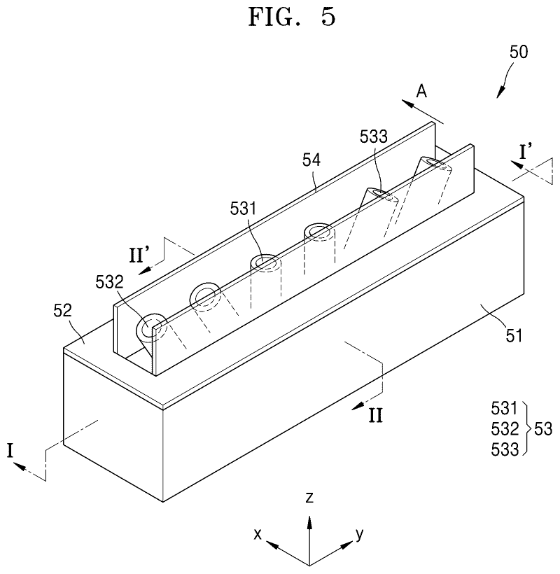

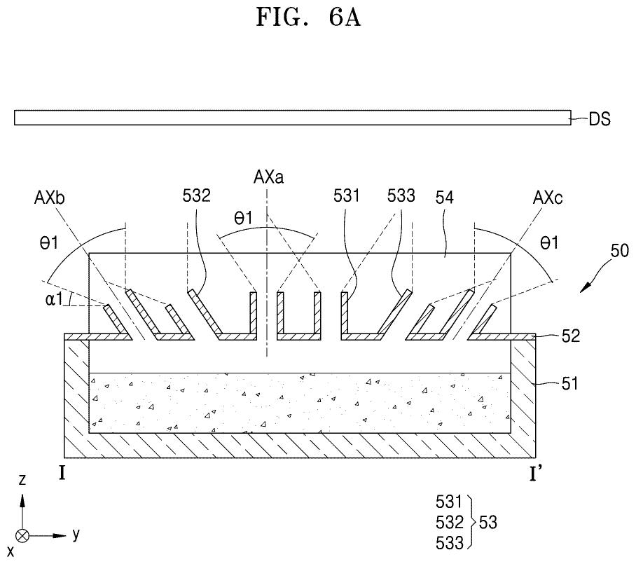

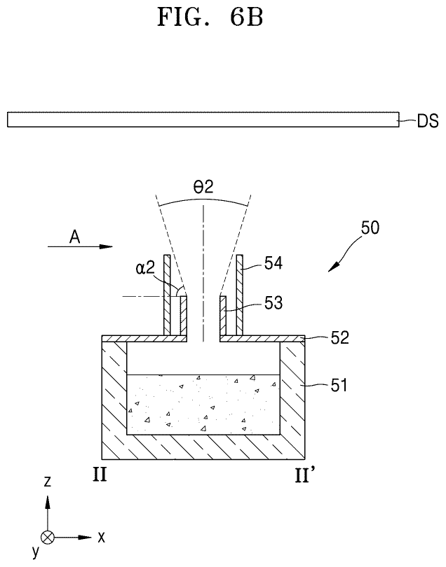

FIG. 5 is a schematic perspective view of the deposition source 50 according to an embodiment, FIG. 6A is a schematic cross-sectional view of the deposition source 50, taken along line I-I′ of FIG. 5 according to an embodiment, and FIG. 6B is a schematic cross-sectional view of the deposition source 50, taken along line II-II′ of FIG. 5 according to an embodiment.

Referring to FIG. 5, in an embodiment, the deposition source 50 may include a housing 51, a cover portion 52, a nozzle 53, and an angle limit plate 54.

The housing 51 is a rigid body having an inner space and may accommodate the deposition material in the inner space. In an embodiment, the housing 51 may be formed in a rectangular shape but is not necessarily limited thereto and may be formed in various shapes such as a cylindrical shape.

The housing 51 may have a shape in which a surface (e.g., surface facing a +z direction) is open. The deposition material may be accommodated in the inner space of the housing 51. A heater may be disposed in the housing 51. The heater may evaporate or sublimate the deposition material by heating the deposition material accommodated in the inner space of the housing 51.

The cover portion 52 may be disposed on an open surface (e.g., single open surface) of the housing 51. The cover portion 52 may close the housing 51 by covering (or overlapping) the open surface (e.g., single open surface) of the housing 51.

The nozzle 53 may be disposed in the cover portion 52. The nozzle 53 may be connected to the cover portion 52 in various shapes. As an example, the nozzle 53 and the cover portion 52 may be integral with each other. In an embodiment, the nozzle 53 may be formed separately from the cover portion 52 and coupled to the cover portion 52. The nozzle 53 may be connected to the inner space of the housing 51 through the cover portion 52. The nozzle 53 may be disposed in an opening provided in the cover portion 52. The deposition material may be sprayed through the nozzle 53.

The nozzle 53 may be formed in various shapes. As an example, the nozzle 53 may have a cylindrical shape or a polygonal column shape.

The nozzle 53 may be provided in plural. As an example, although six nozzles 53 may be provided as shown in FIGS. 5 and 6A, the embodiment is not limited thereto. The number of nozzles 53 may be changed depending on the display substrate DS and the size of the mask sheet 42.

The nozzles 53 may be disposed side-by-side in the direction parallel to a side (e.g., single side) of the display substrate DS. The nozzles 53 may be disposed apart from each other at an equal interval.

The deposition source 50 may continuously perform deposition while moving relative to the display substrate DS. For example, the deposition source 50 may perform deposition in a scanning manner while moving in a direction (hereinafter, referred to as a ‘movement direction of the deposition source’) of an arrow A relative to the display substrate DS. Although it is shown in FIGS. 5 and 6B that the deposition source 50 performs deposition while moving relative to the display substrate DS in the x direction inside the chamber, the disclosure is not necessarily limited thereto. In an embodiment, the deposition source 50 is fixed and deposition may be performed while the display substrate DS itself moves in the x direction.

In other words, the deposition source 50 may spray the deposition material while moving relative to the display substrate DS in the x direction. The nozzles 53 may be disposed side-by-side in a direction (hereinafter, referred to as a ‘nozzle direction of the deposition source’) perpendicular to the movement direction A of the deposition source 50. The deposition source 50 with this configuration may deposit the deposition material on the entire surface of the display substrate DS.

Referring to FIGS. 5 and 6A, the nozzles 53 may include a first nozzle 531, a second nozzle 532, and a third nozzle 533. In an embodiment, at least some of the nozzles 53 may be tilted at a preset angle. As an example, at least some of the nozzles 53 may be tilted at a preset angle on an yz-plane. As an example, the second nozzle 532 may be disposed on a side (e.g., single side in a −y direction) of the first nozzle 531, and the third nozzle 533 may be disposed on another side (e.g., in a +y direction) of the first nozzle 531. A central axis AXa of the first nozzle 531 may be parallel to a z axis on the yz-plane. The second nozzle 532 and the third nozzle 533 may be tilted at a preset angle on the yz-plane. For example, a central axis AXb of the second nozzle 532 and a central axis AXc of the third nozzle 533 may be tilted at a preset angle with respect to a z axis on the yz-plane.

In an embodiment, some of the nozzles 53 may be tilted at a different angle and/or a different direction with respect to other some of the nozzles 53. As an example, the second nozzle 532 and the third nozzle 533 may be tilted in directions opposite each other. The central axis AXb of the second nozzle 532 may be tilted in the −y direction with respect to the z axis on the yz-plane. The central axis AXc of the third nozzle 533 may be tilted in the +y direction with respect to the z axis. However, the disclosure is not necessarily limited thereto. In an embodiment, the second nozzle 532 and the third nozzle 533 may be tilted to face each other.

Each of the nozzles 53 may spray the deposition material toward the display substrate DS at a preset spray angle θ1. A minimum incident angle α1 of the deposition material incident to the display substrate DS may change depending on the degree to which each of the nozzles 53 is tilted. As an example, as the degree to which some of the nozzles 53 are tilted increases, the minimum incident angle α1 of the deposition material incident to the display substrate DS may be reduced.

Because the deposition source 50 includes the nozzles 53 and some of the nozzles 53 are tilted at a preset angle, the deposition material may be entirely deposited on the display substrate DS in the nozzle direction (e.g., y direction) of the deposition source 50. The deposition material may be deposited in the nozzle direction (e.g., y direction) of the deposition source 50 on the display substrate DS to a uniform thickness.

Referring to FIGS. 5 and 6B, the deposition source 50 may include the angle limit plate 54. The angle limit plate 54 may be disposed on the cover portion 52. The angle limit plate 54 may be disposed on two opposite sides of the opening in which the nozzles 53 are disposed. The angle limit plates 54 may extend in parallel to a direction in which the nozzles 53 are disposed side-by-side. For example, the angle limit plates 54 may extend in the nozzle direction (e.g., y direction) of the deposition source 50. The angle limit plates 54 may be disposed apart from each other in a direction perpendicular to the nozzle direction of the deposition source 50. For example, the angle limit plates 54 may be disposed apart from each other in the movement direction (e.g., x direction) of the deposition source 50.

The angle limit plate 54 may limit a spray angle of the deposition material sprayed from the nozzle 53 to the display substrate DS. Unlike the nozzle direction of the deposition source 50, because the deposition source 50 performs deposition on the display substrate DS while moving in the movement direction A of the deposition source 50 relative to the display substrate DS, the angle limit plate 54 may be introduced to improve the straightness of the deposition material.

A spray angle of the deposition material may change depending on the height of the angle limit plate 54. As the height of the angle limit plate 54 increases, a spray angle θ2 of the deposition material may be reduced. As an example, a spray angle θ2 of the nozzle 53 in the movement direction A (e.g., x direction) of the deposition source 50 may be less than a spray angle θ1 of the nozzle 53 in the nozzle direction (e.g., y direction) of the deposition source 50. As the spray angle θ2 of the deposition material is small, a minimum incident angle α2 of the deposition material incident to the display substrate DS may increase.

Referring to FIGS. 5, 6A, and 6B, the minimum incident angle α1 of the deposition material incident to the display substrate DS in the nozzle direction (e.g., y direction) of the deposition source 50 may be less than the minimum incident angle α2 of the deposition material incident to the display substrate DS in the movement direction A (e.g., x direction) of the deposition source 50.

As described above with reference to FIG. 3B, the inner shadow region (e.g., region A2 of FIG. 3B) may appear different depending on the minimum incident angle α of the deposition material incident to the display substrate DS. Because the minimum incident angle α1 of the deposition material in the nozzle direction (e.g., y direction) of the deposition source 50 is less than the minimum incident angle α2 of the deposition material in the movement direction A (e.g., x direction) of the deposition source 50, the inner shadow region may appear larger in the nozzle direction (e.g., y direction) of the deposition source 50 than in the movement direction A (e.g., x direction) of the deposition source 50.

A deviation in the inner shadow region between the movement direction A (e.g., x direction) of the deposition source 50 and the nozzle direction (e.g., y direction) of the deposition source 50 may appear remarkable at the intermediate point MP of the mask sheet 42 which is described with reference to FIG. 4B and on which the minimum magnetic force acts.

According to the disclosure, an interval between sub-pixels in the movement direction A of the deposition source 50, and an interval between sub-pixels in the nozzle direction of the deposition source 50 may be designed to be different by taking into account a deviation in the inner shadow. Accordingly, a deposition uniformity in the movement direction A (e.g., x direction) of the deposition source 50 and the nozzle direction (e.g., y direction) of the deposition source 50 may be improved. Accordingly, a spot defect of the display panel due to magnetic force patterns may be reduced. Hereinafter, the arrangement structure of the sub-pixels according to an embodiment is specifically described below.

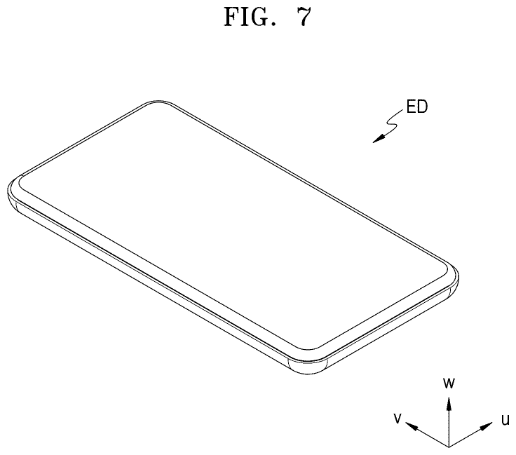

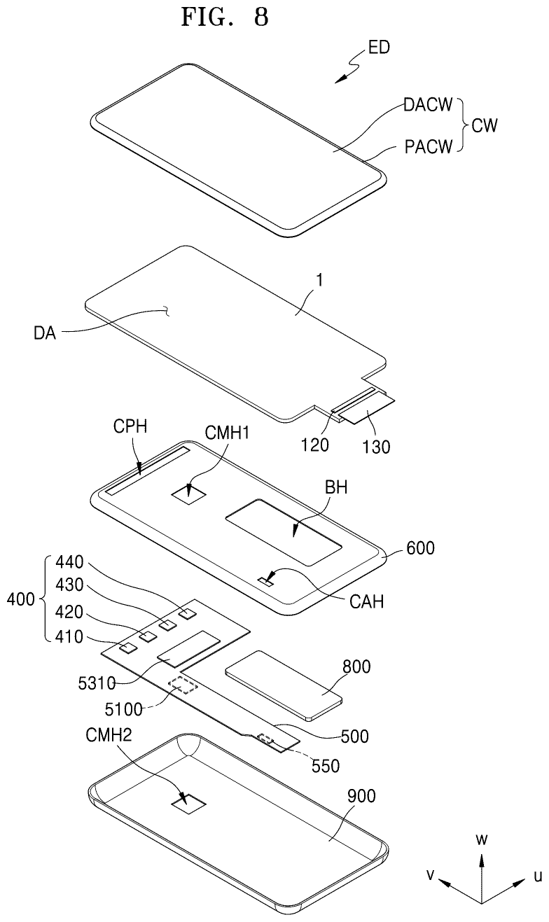

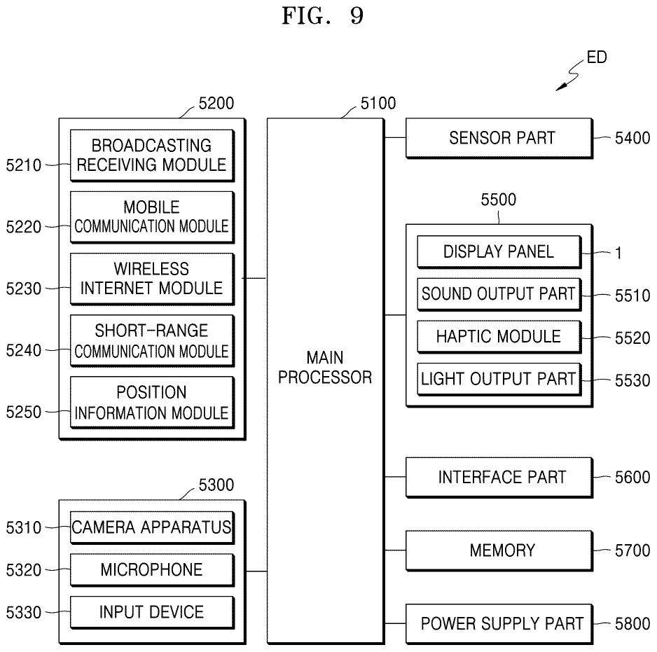

FIG. 7 is a schematic perspective view of an electronic apparatus ED according to an embodiment, FIG. 8 is a schematic exploded perspective view of the electronic apparatus ED of FIG. 7, and FIG. 9 is a schematic block diagram of the electronic apparatus ED of FIG. 7.

Referring to FIGS. 7 and 8, the electronic apparatus ED according to an embodiment may be an apparatus for displaying moving images or still images and may be various products including televisions, notebook computers, monitors, advertisement boards, Internet of things (IoTs) as well as portable electronic apparatuses including mobile phones, smart phones, tablet personal computers (PCs), mobile communication terminals, electronic organizers, electronic books, portable multimedia players (PMPs), navigations, and ultra mobile personal computers (UMPCs). The electronic apparatus ED according to an embodiment may include wearable devices including smartwatches, watchphones, glasses-type displays, or head-mounted displays (HMDs). In an embodiment, the electronic apparatus ED may be an instrument panel for automobiles, center fascias for automobiles, or center information displays (CIDs) disposed on a dashboard, room mirror displays that replace side mirrors of automobiles, and displays arranged on the backside of front seats as an entertainment for back seats of automobiles.

FIGS. 7 and 8 show, for convenience of description, that the electronic apparatus ED according to an embodiment is a smartphone. The electronic apparatus ED may include a cover window CW, a display panel 1, a data driver 120, a display circuit board 130, a component 400, a bracket 600, a main circuit board 500, a battery 800, and/or a lower cover 900.

The electronic apparatus ED may appear to have an approximately rectangular shape in a plan view. As an example, as shown in FIG. 7, the electronic apparatus ED may appear to have an approximately rectangular shape having short sides in a u direction and long sides in a v direction on a uv-plane. An edge where a short side in the u direction meets a long side in the v direction may form a right angle, or may have a round shape with a preset curvature. In a plan view, the electronic apparatus ED may have a polygonal shape instead of a rectangular shape, and may have an elliptical shape or an irregular shape.

The cover window CW may be disposed on (in a w direction) the display panel 1 to cover the upper surface of the display panel 1. The cover window CW may be configured to protect the upper surface of the display panel 1.

The cover window CW may include a transmissive cover portion DACW and a light-blocking cover portion PACW, and the transmissive cover portion DACW may correspond to the display panel 1, and the light-blocking cover portion PACW surrounds the transmissive cover portion DACW. The light-blocking cover portion PACW may include an opaque material (e.g., a colored opaque material) that blocks light. The light-blocking cover portion PACW may include a pattern that may be viewed to a user while images are not displayed.

The display panel 1 may be disposed under the cover window CW. The display panel 1 may overlap the transmissive cover portion DACW of the cover window CW. The display panel 1 may include a display area DA. The display area DA may be a region in which images are displayed, and may include a region (referred to as a component area, hereinafter) that transmits light emitted from the component 400 disposed below the display panel 1. The component may include sensors and cameras that use visible light, infrared light, sound, and the like.

The display panel 1 may be a light-emitting display panel including a light-emitting diode. The light-emitting diode may include an organic light-emitting diode including an organic emission layer, or an inorganic light-emitting diode including an inorganic material. The inorganic light-emitting diode may include a PN diode including inorganic material semiconductor-based materials. In case that a forward voltage is applied to a PN-junction diode, holes and electrons are injected, and light of a preset color may be emitted while energy created by recombination of the holes and the electrons is converted to light energy. The inorganic light-emitting diode may have a width of several micrometers to hundreds of micrometers. The inorganic light-emitting diode may be denoted by a micro light-emitting diode.

The display panel 1 may be a rigid display panel that has rigidity and thus is not readily bent, or a flexible display panel that has flexibility and thus is readily bendable, foldable, or rollable. As an example, the display panel 1 may include a foldable display panel that folds and unfolds, a curved display panel that has a curved display surface, a flexible display panel in which a region except a display surface is bent, a rollable display panel that is rollable and unrollable, or a stretchable display panel that is stretchable.

The display panel 1 may be implemented transparent and be a transparent display panel such that an object or background disposed below the display panel 1 is viewable from the upper surface of the display panel 1. The display panel 1 may be a reflective display panel that may reflect an object or background over the upper surface of the display panel 1.

The data driver 120 may be mounted in the form of an integrated circuit (IC) on the display panel 1. However, the disclosure is not limited thereto, and, for example, the data driver 120 may be mounted on the display circuit board 130.

The display circuit board 130 may be attached on a side of the display panel 1. The display circuit board 130 may be a flexible printed circuit board (FPCB) that may be bent, a rigid printed circuit board (PCB) that is strong and not readily bent, or a composite printed circuit board including both a rigid printed circuit board and a flexible printed circuit board. A touch sensor driver may be mounted on the display circuit board 130. The touch sensor driver may include an integrated circuit. The touch sensor driver may be electrically connected to touch electrodes of a touch sensor layer of the display panel 1 through the display circuit board 130.

The touch sensor layer of the display panel 1 may sense a user's touch input by using at least one of various touch methods such as a resistance layer method, a capacitance method and the like. In the case where the touch sensor layer of the display panel 1 senses a user's touch input by using a capacitance method, the touch sensor driver may determine whether a user touches the touch sensor layer by applying driving signals to driving electrodes among touch electrodes, and sensing voltages charged in a mutual capacitance between the driving electrodes and the sensing electrodes through the sensing electrodes among the touch electrodes.

A user's touch may include a contact touch and a proximity touch. A contact touch denotes that an object such as a user's finger or a pen is in direct contact with the cover window CW disposed on the touch sensor layer. A proximity touch, like hovering, denotes that an object such as a user's finger or a pen is located near over the cover window CW, away from the cover window CW. The touch sensor driver may be configured to transfer sensor data to a main processor 5100 according to sensed voltages, and the main processor 5100 may be configured to calculate touch coordinates at which a touch input occurs by analyzing the sensor data.

A controller may be disposed on the display circuit board 130, and the controller may be configured to supply driving voltages for driving pixels of the display panel 1, a gate driver, and/or the data driver 120.

The bracket 600 for supporting the display panel 1 may be disposed under the display panel 1. The bracket 600 may include plastic, metal, or both plastic and metal. The bracket 600 may include a first camera hole CMH1 to which a camera apparatus 5310 is inserted, a battery hole BH in which the battery 800 is disposed, a cable hole CAH through which a cable connected to the display circuit board 130 passes, and a component hole CPH corresponding to the components 400. The component hole CPH may overlap the components 400 of the main circuit board 500 when viewed in a third direction (z axis direction). For reference, the display area DA of the display panel 1 may overlap the components 400 of the main circuit board 500 when viewed in the third direction (z axis direction). When needed, the bracket 600 may not include the component hole CPH.

The component 400 included in the electronic apparatus ED may include a first component 410, a second component 420, a third component 430, and a fourth component 440 overlapping the display panel 1. Each of the first component 410, the second component 420, the third component 430, and the fourth component 440 may include at least one of a proximity sensor, an illuminance sensor, an iris sensor, a face recognition sensor, and a camera (or image sensor). A proximity sensor that uses an infrared ray may detect an object located close to the upper surface of the electronic apparatus ED, and an illuminance sensor may detect brightness of light incident to the upper surface of the electronic apparatus ED. An iris sensor may capture a person's iris located on the upper surface of the electronic apparatus ED, and a camera may obtain image data of an object disposed on an upper surface of the electronic apparatus ED. The component 400 is not limited to the proximity sensor, the illuminance sensor, the iris sensor, the face recognition sensor, and/or the camera. The component 400 may include another sensor.

The main circuit board 500 and the battery 800 may be disposed under the bracket 600. The main circuit board 500 may be a printed circuit board or a flexible printed circuit board.

The main circuit board 500 may include the main processor 5100, the camera apparatus 5310, a main connector 550, and the components 400. The main processor 5100 may include an integrated circuit. When needed, the electronic apparatus ED may include not only the camera apparatus 5310 disposed on the upper surface of the main circuit board 500, but also a camera apparatus disposed under the lower surface of the main circuit board 500. Each of the main processor 5100 and the main connector 550 may be disposed on one of the upper surface and the lower surface of the main circuit board 500. The main circuit board 500 may be electrically connected to the display circuit board 130 through the main connector 550 and the like.

The main processor 5100 may be configured to control all functions of the electronic apparatus ED. As an example, the main processor 5100 may be configured to output digital video data to the data driver 120 through the display circuit board 130 such that the display panel 1 displays images. The main processor 5100 may be configured to receive sensed data from the touch sensor driver. The main processor 5100 may determine whether a user touches a touchscreen according to sensed data, and execute an operation corresponding to a user's direct touch or proximity touch. The main processor 5100 may be an application processor including an integrated circuit, a central processing unit, or a system chip.

The camera apparatus 5310 processes image frames such as still images or moving images obtained by an image sensor in a camera mode, and outputs the image frames to the main processor 5100. The camera apparatus 5310 may include at least one of a camera sensor (e.g., a charge-coupled device (CCD), a complementary metal oxide semiconductor (CMOS), or the like), a photo sensor (or an image sensor), and a laser sensor.

A cable passing through the cable hole CAH of the bracket 600 may be connected to the main connector 550, and the main circuit board 500 may be electrically connected to the display circuit board 130 through the cable.

The electronic apparatus ED may be represented as a block diagram shown in FIG. 9. The electronic apparatus ED may include not only the main processor 5100 but also a wireless communication part 5200, an input part 5300, a sensor part 5400, an output part 5500, an interface part 5600, a memory 5700, and/or a power supply part 5800 as shown in FIG. 9.

The wireless communication part 5200 may include at least one of a broadcasting receiving module 5210, a mobile communication module 5220, a wireless Internet module 5230, a short-range communication module 5240, and a position information module 5250.

The broadcasting receiving module 5210 may be configured to receive broadcasting signals and/or broadcasting-related information from an external broadcasting management server through a broadcasting channel. The broadcasting channel may include satellite channels or groundwave channels.

The mobile communication module 5220 may be configured to transmit/receive radio signals to/from at least one of a base station, an external terminal, and a server on a mobile communication network established according to technology standards for mobile communication or communication schemes (e.g., Global System for Mobile communication (GSM), Code Division Multi Access (CDMA), Code Division Multi Access 2000 (CDMA2000), Enhanced Voice-Data Optimized or Enhanced Voice-Data Only (EV-DO), Wideband CDMA (WCDMA), High Speed Downlink Packet Access (HSDPA), High Speed Uplink Packet Access (HSUPA), Long Term Evolution (LTE), Long Term Evolution-Advanced (LTE-A), and the like). Wireless signals may include voice call signals, image communication call signals, or various types of data corresponding to text/multimedia message transmission/reception.

The wireless Internet module 5230 denotes a module for wireless Internet access. The wireless Internet module 5230 may be configured to transmit/receive radio signals on a communication network according to wireless Internet technologies. Examples of wireless Internet technologies may include wireless local area network (WLAN), wireless-fidelity (Wi-Fi), Wi-Fi Direct, and/or digital living network alliance (DLNA).

The short-range communication module 5240 may be for short-range communication, and may support short distance communication by using at least one of Bluetooth™, Radio Frequency Identification (RFID), Infrared Data Association; IrDA (IrDA), Ultra-Wideband (UWB), ZigBee, Near Field Communication (NFC), Wi-Fi, Wi-Fi Direct, and Wireless Universal Serial Bus (Wireless USB) technologies. The short-range communication module 5240 may support wireless communication between the electronic apparatus ED and a wireless communication system, between the electronic apparatus ED and another electronic apparatus, or between the electronic apparatus ED and a network in which another the electronic apparatus (or an external server) is located, through a short distance wireless area network. The short distance wireless area network may be a wireless personal area network. Another electronic apparatus may be a wearable device that may exchange data, or operate with the electronic apparatus ED.

The position information module 5250 may be a module for obtaining the position of the electronic apparatus ED, and may include a Global Positioning System (GPS) module or a Wi-Fi module.

The input part 5300 may include an image input part such as the camera apparatus 5310 for inputting image signals, a sound input part such as a microphone 5320 for inputting sound signals, and an input device 5330 for receiving information from a user. The camera apparatus 5310 processes image frames such as still images or moving images obtained by an image sensor in an image communication mode or a photographing mode. The processed image frames may be displayed on the display panel 1 or stored in the memory 5700. The microphone 5320 processes external sound signals as electrical voice data. The processed voice data may be variously utilized according to a function (or an application in execution) being performed in the electronic apparatus ED.

The main processor 5100 may control an operation of the electronic apparatus ED to correspond to information input through the input device 5330. The input device 5330 may include a mechanical input means such as buttons, a dome switch, a jog wheel, a jog switch, and the like, or a touch input means located on the lower surface or the lateral surface of the electronic apparatus ED. The touch input means may include the touch sensor layer of the display panel 1.

The sensor part 5400 may include at least one sensor that senses at least one of information inside the electronic apparatus ED, peripheral environmental information surrounding the electronic apparatus ED, and user information, and generates sensing signals corresponding thereto. The main processor 5100 may control driving or an operation of the electronic apparatus ED based on the sensing signals, or perform data processing, a function, or an operation related to an application installed in the electronic apparatus ED. The sensor part 5400 may be the proximity sensor, the illuminance sensor, or the face recognition sensor as described above with association with the component 400. The sensor part 5400 may include an acceleration sensor, a magnetic sensor, a G-sensor, a gyroscope sensor, a motion sensor, an RGB sensor, an infrared (IR) sensor, a finger scan sensor, an ultrasonic sensor, an optical sensor, and/or a battery gauge. The sensor part 5400 may include an environmental sensor or a chemical sensor. The environmental sensors may include, for example, a barometer, a hygrometer, a thermometer, a radiation detection sensor, a heat detection sensor, and/or a gas detection sensor. Chemical sensors may include, for example, an electronic nose, a healthcare sensor, and/or a biometric recognition sensor.

The output part 5500 is for generating an output related to a visual sense, an auditory sense, or a tactile sense, and may include at least one of the display panel 1, a sound output part 5510, a haptic module 5520, and a light output part 5530.

The display panel 1 displays (outputs) information processed by the electronic apparatus ED. As an example, the display panel 1 may display execution screen information of an application driven by the electronic apparatus ED, user interface (UI), or graphic user interface (GUI) information corresponding to the execution screen information. The display panel 1 may include a display layer and the touchscreen layer, and the display layer may display images, and the touch sensor layer senses a user's touch input. Accordingly, the display panel 1 may serve as one of the input devices 5330 that provide an input interface between the electronic apparatus ED and a user, and simultaneously, serve as one of the output parts 5500 that provide an output interface between the electronic apparatus ED and a user.

The sound output part 5510 may output sound data received by the wireless communication part 5200 or stored in the memory 5700 in a call reception mode, a communication mode or recording mode, a voice recognition mode, a broadcasting reception mode, and the like. The sound output part 5510 may output sound signals related to a function (e.g., a call signal reception tone, a message reception tone, and the like) performed by the electronic apparatus ED. The sound output part 5510 may include a receiver and a speaker. At least one of the receiver and the speaker may be a sound generator that is attached under the display panel 1 and vibrates the display panel 1 to output sounds. The sound generator may be a piezoelectric element or a piezoelectric actuator that contacts and expands according to electrical signals, or an exciter that generates magnetic force by using a voice coil to vibrate the display panel 1.

The haptic module 5520 generates various haptic effects that may be felt by a user. The haptic module 5520 may provide vibrations to a user as a haptic effect. The haptic module 5520 may not only transfer a tactile effect through a direct contact but implement a tactile effect such that a user may feel the tactile effect through a muscle sense in fingers or arms.

The light output part 5530 outputs signals for informing occurrence of an event by using light of a light source. Examples of an event generated in the electronic apparatus ED may include message reception, call signal reception, a missed call, alarm, schedule notification, e-mail reception, and/or information reception through an application, and the like. Signals output by the light output part 5530 may be implemented in case that the electronic apparatus ED emits light of a single color or multiple colors to the front surface or the rear surface. The signal output may end in case the electronic apparatus ED detects that a user confirms an event.

The interface part 5600 serves as a path with various kinds of external apparatuses connected to the electronic apparatus ED. The interface part 5600 may include at least one of a wired/wireless headset port, an external charger port, a wired/wireless data port, a memory card part, a port for connecting an apparatus having an identification module, an audio input/output (I/O) port, a video I/O port, and an carphone port. In case that an external apparatus is connected to the interface part 5600, the electronic apparatus ED may perform an appropriate control related to the external apparatus connected.

The memory 5700 stores data that support various functions of the electronic apparatus ED. The memory 5700 may store multiple application programs driven in the electronic apparatus ED, data and/or commands for operations of the electronic apparatus ED. At least some of the application programs may be downloaded from an external server through wireless communication. The memory 5700 may store an application program for operations of the main processor 5100, and temporarily store data input/output, for example, data such as a phone book, messages, still images, and/or moving images. The memory 5700 may store haptic data for various patterns of vibrations provided to the haptic module 5520, and sound data regarding various sounds provided to the sound output part 5510.

The memory 5700 may include at least one type of storing medium among a flash memory type, a hard disk type, a solid state disk (SSD) type, a silicon disk drive (SDD) type, a multimedia card micro type, a card type memory (e.g., secure digital (SD) or extreme digital (XD) memory), a random access memory (RAM), a static random access memory (SRAM), a read-only memory (ROM), an electrically erasable programmable read-only memory (EEPROM), a programmable read-only memory (PROM), a magnetic memory, a magnetic disk, and an optical disk.

The power supply part 5800 receives an external power and/or an internal power under control of the main processor 5100, and supplies power to respective elements included in the electronic apparatus ED. The power supply part 5800 may include the battery 800. The power supply part 5800 may include a connection port. The connection port may be an example of the interface part 5600 to which an external charger is electrically connected, and the external charger may supply power to charge the battery 800. The power supply part 5800 may charge the battery 800 wirelessly. The battery 800 may be arranged not to overlap the main circuit board 500 in the third direction (the z direction). The battery 800 may overlap the battery hole BH of the bracket 600.

The lower cover 900 may form an exterior of the electronic apparatus ED and have an opening exposing a portion of the display panel 1. The lower cover 900 has an open shape corresponding to the display panel 1 and may be fastened to the display panel 1. The lower cover 900 may be located on the opposite side of the cover window CW with the display panel 1 therebetween. The lower cover 900 may be disposed under the main circuit board 500 and the battery 800. The lower cover 900 may be fastened and fixed to the bracket 600. The lower cover 900 may form the lower exterior of the electronic apparatus ED. The lower cover 900 may include plastic, metal, or both plastic and metal.

A second camera hole CMH2 through which the lower surface of the camera apparatus 5310 is exposed may be formed in the lower cover 900. The positions of the camera apparatus 5310 and the first and second camera holes CMH1 and CMH2 corresponding to the camera apparatus 5310 are not limited to the embodiment shown in FIGS. 8 and 9, but may be variously modified.

FIG. 10 is a schematic perspective view of the display panel 1 manufactured through an apparatus for manufacturing the display panel 1 according to an embodiment.

Referring to FIG. 10, the display panel 1 manufactured according to an embodiment may include the display area DA and a peripheral area PA outside the display area DA. The display panel 1 may be configured to display images through an array of multiple sub-pixels arranged two-dimensionally in the display area DA.

The peripheral area PA may be a region that does not display images and may surround the display area DA entirely or partially. A driver and the like configured to provide electric signals or power to sub-pixel circuits respectively corresponding to the sub-pixels may be arranged in the peripheral area PA. A pad may be disposed in the peripheral area PA, and the pad may be a region to which electronic elements or a printed circuit board may be electrically connected.

The display panel 1 may be provided in various shapes, for example, the display panel 1 may be provided in a rectangular plate shape having two pairs of sides parallel to each other. In the case where the display panel 1 is provided in a rectangular plate shape, a pair (e.g., single pair) of sides of the two pairs of sides may be provided longer than another pair of sides. In an embodiment, for convenience of description, the case where the display panel 1 has a rectangular shape having a pair of first sides and a pair of second sides, is provided, in which an extension direction of the first sides is denoted by a first direction (u direction), an extension direction of the second sides is denoted by a second direction (v direction), and a direction perpendicular to the extension directions of the first sides and the second sides is denoted by a third direction (w direction). It is shown in FIG. 10 that the first side of the rectangular shape of the display panel 1 is a short side, and the second side is a long side. In an embodiment, the first side of the rectangular shape of the display panel 1 may be a long side, and the second side may be a short side. In an embodiment, the display panel 1 may be, for example, a circular shape, an elliptical shape, a polygonal shape including a portion having a circular shape, and a polygon excluding a quadrangle.

Although it is described below that the display panel 1 includes an organic light-emitting diode OLED as a display element, the display panel 1 according to the disclosure is not necessarily limited thereto. In an embodiment, the display panel 1 may be a light-emitting display panel including an inorganic light-emitting diode, that is, an inorganic light-emitting display panel. The inorganic light-emitting diode may include a PN diode including inorganic material semiconductor-based materials. In case that a forward voltage is applied to a PN-junction diode, holes and electrons are injected, and light of a preset color may be emitted while energy created by recombination of the holes and the electrons is converted to light energy. The inorganic light-emitting diode may have a width in the range of several micrometers to hundreds of micrometers. In an embodiment, the inorganic light-emitting diode may be denoted by a micro light-emitting diode. In an embodiment, the display panel 1 may be a quantum-dot light-emitting display panel.

As described above, the display panel 1 may be used as a display screen in various products including televisions, notebook computers, monitors, advertisement boards, Internet of things (IoTs) as well as portable electronic apparatuses including mobile phones, smartphones, tablet personal computers (PCs), mobile communication terminals, electronic organizers, electronic books, portable multimedia players (PMPs), navigations, and ultra mobile personal computers (UMPCs). The display panel 1 according to an embodiment may be used in wearable devices including smartwatches, watchphones, glasses-type displays, and head-mounted displays (HMDs). In addition, in an embodiment, the display panel 1 is used as a display screen in instrument panels for automobiles, center fascias for automobiles, or center information displays (CIDs) arranged on a dashboard, room mirror displays that replace side mirrors of automobiles, and displays arranged on the backside of front seats as an entertainment for back seats of automobiles.

FIG. 11 is a schematic cross-sectional view of a portion of the display area DA of the display panel 1 according to an embodiment.

Referring to FIG. 11, the display panel 1 may include a stack structure of the substrate 100, a sub-pixel circuit layer PCL, a display element layer DEL, and an encapsulation layer 300.

The substrate 100 may have a multi-layered structure including a base layer that includes the polymer resin and an inorganic layer. As an example, the substrate 100 may include the base layer including a polymer resin and a barrier layer including an inorganic insulating layer. As an example, the substrate 100 may include a first base layer 101, a first barrier layer 102, a second base layer 103, and a second barrier layer 104 that are sequentially stacked on each other. The first base layer 101 and the second base layer 103 may each include polyimide (PI), polyethersulfone (PES), polyarylate, polyetherimide (PEI), polyethylene naphthalate (PEN), polyethylene terephthalate (PET), polyphenylene sulfide (PPS), polycarbonate (PC), cellulose tri acetate (TAC), and/or cellulose acetate propionate (CAP). The first barrier layer 102 and the second barrier layer 104 may each include an inorganic insulating material such as silicon oxide, silicon oxynitride, and/or silicon nitride. The substrate 100 may be flexible.

The sub-pixel circuit layer PCL is disposed on the substrate 100. It is, for example, shown in FIG. 11 that the sub-pixel circuit layer PCL includes a thin-film transistor TFT, a buffer layer 111, a first gate insulating layer 112, a second gate insulating layer 113, an interlayer insulating layer 114, and a first planarization insulating layer 115, and a second planarization insulating layer 116 under and/or on elements of the thin-film transistor TFT.

The buffer layer 111 may reduce or block foreign material, moisture, or external air penetrating from below the substrate 100 and may provide an approximately flat surface on the substrate 100. The buffer layer 111 may include an inorganic insulating material such as silicon nitride, silicon oxynitride, and silicon oxide, and include a single-layered structure or a multi-layered structure including the above materials.

The thin-film transistor TFT on the buffer layer 111 may include a semiconductor layer Act, and the semiconductor layer Act may include polycrystalline silicon. The semiconductor layer Act may include amorphous silicon, an oxide semiconductor, an organic semiconductor, or a combination thereof. The semiconductor layer Act may include a channel region C, a drain region D, and a source region S respectively disposed on two opposite sides of the channel region C. A gate electrode GE may overlap the channel region C.

The gate electrode GE may include a low-resistance metal material. The gate electrode GE may include a conductive material including molybdenum (Mo), aluminum (Al), copper (Cu), and titanium (Ti) and have a single-layered structure or a multi-layered structure including the above materials.

The first gate insulating layer 112 between the semiconductor layer Act and the gate electrode GE may include an inorganic insulating material such as silicon oxide, silicon nitride, silicon oxynitride, aluminum oxide, titanium oxide, tantalum oxide, hafnium oxide, zinc oxide, or a combination thereof. Zinc oxide may be zinc oxide and/or zinc peroxide.

The second gate insulating layer 113 may cover (or overlap) the gate electrode GE. Similar to the first gate insulating layer 112, the second gate insulating layer 113 may include an inorganic insulating material such as silicon oxide, silicon nitride, silicon oxynitride, aluminum oxide, titanium oxide, tantalum oxide, hafnium oxide, zinc oxide, or a combination thereof. Zinc oxide may be zinc oxide and/or zinc peroxide.

An upper electrode Cst2 of a storage capacitor Cst may be disposed on the second gate insulating layer 113. The upper electrode Cst2 may overlap the gate electrode GE disposed below the upper electrode Cst2. The gate electrode GE and the upper electrode Cst2 overlapping each other with the second gate insulating layer 113 therebetween may constitute the storage capacitor Cst. For example, the gate electrode GE may serve as a lower electrode Cst1 of the storage capacitor Cst.

As described above, the storage capacitor Cst may overlap the thin-film transistor TFT. In an embodiment, the storage capacitor Cst may be formed not to overlap the thin-film transistor TFT.

The upper electrode Cst2 may include aluminum (Al), platinum (Pt), palladium (Pd), silver (Ag), magnesium (Mg), gold (Au), nickel (Ni), neodymium (Nd), iridium (Ir), chrome (Cr), calcium (Ca), molybdenum (Mo), titanium (Ti), tungsten (W), copper (Cu), or a combination thereof, and include a single layer or a multi-layer including the above materials.

The interlayer insulating layer 114 may cover (or overlap) the upper electrode Cst2. The interlayer insulating layer 114 may include an inorganic insulating material such as silicon oxide, silicon nitride, silicon oxynitride, aluminum oxide, titanium oxide, tantalum oxide, hafnium oxide, zinc oxide, or a combination thereof. Zinc oxide may be zinc oxide and/or zinc peroxide. The interlayer insulating layer 114 may include a single layer or a multi-layer including the inorganic insulating material.

A drain electrode DE and a source electrode SE may each be disposed on the interlayer insulating layer 114. The drain electrode DE and the source electrode SE may be respectively connected to the drain region D and the source region S through contact holes of insulating layers disposed below the drain electrode DE and the source electrode SE. The drain electrode DE and the source electrode SE may each include a material having high conductivity. The drain electrode DE and the source electrode SE may each include a conductive material including molybdenum (Mo), aluminum (Al), copper (Cu), titanium (Ti), or a combination thereof, and include a single layer or a multi-layer including the above materials. In an embodiment, the drain electrode DE and the source electrode SE may each have a multi-layered structure of Ti/Al/Ti.

The first planarization insulating layer 115 may cover (or overlap) the drain electrode DE and the source electrode SE. The first planarization insulating layer 115 may include an organic insulating material including a general-purpose polymer such as polymethylmethacrylate (PMMA) or polystyrene (PS), polymer derivatives having a phenol-based group, an acryl-based polymer, an imide-based polymer, an aryl ether-based polymer, an amide-based polymer, a fluorine-based polymer, a p-xylene-based polymer, a vinyl alcohol-based polymer, and a blend thereof.

The second planarization insulating layer 116 may be disposed on the first planarization insulating layer 115. The second planarization insulating layer 116 and the first planarization insulating layer 115 may include a same material and may include an organic insulating material including a general-purpose polymer such as polymethylmethacrylate (PMMA) or polystyrene (PS), polymer derivatives having a phenol-based group, an acryl-based polymer, an imide-based polymer, an aryl ether-based polymer, an amide-based polymer, a fluorine-based polymer, a p-xylene-based polymer, a vinyl alcohol-based polymer, and a blend thereof.

The display element layer DEL may be disposed on the sub-pixel circuit layer PCL having the above structure. The display element layer DEL may include an organic light-emitting diode OLED as a display element (for example, a light-emitting element). The organic light-emitting diode OLED may have a stack structure of a sub-pixel electrode 210, an intermediate layer 220, and a common electrode 230. The organic light-emitting diode OLED may emit, for example, red, green, or blue light, or emit red, green, blue, or white light. The organic light-emitting diode OLED may be configured to emit light through an emission area EA. The emission area EA may be defined as a sub-pixel PX.

The sub-pixel electrode 210 of the organic light-emitting diode OLED may be electrically connected to the thin-film transistor TFT through contact holes formed in the second planarization insulating layer 116 and the first planarization insulating layer 115, and a connection electrode CM disposed on the first planarization insulating layer 115.

The sub-pixel electrode 210 may include a conductive oxide such as indium tin oxide (ITO), indium zinc oxide (IZO), zinc oxide (ZnO), indium oxide (In₂O₃), indium gallium oxide (IGO), aluminum zinc oxide (AZO), or a combination thereof. In an embodiment, the sub-pixel electrode 210 may include a reflective layer including silver (Ag), magnesium (Mg), aluminum (Al), platinum (Pt), palladium (Pd), gold (Au), nickel (Ni), neodymium (Nd), iridium (Ir), chrome (Cr), a compound thereof, or a combination thereof. In an embodiment, the sub-pixel electrode 210 may further include a layer on/under the reflective layer, the layer may include ITO, IZO, ZnO, In₂O₃, or a combination thereof.

A bank layer 117 may be disposed on the sub-pixel electrode 210, the bank layer 117 including an opening 117OP exposing a central portion of the sub-pixel electrode 210. The bank layer 117 may include an organic insulating material and/or an inorganic insulating material. The opening 117OP of the bank layer 117 may define the emission area EA of light emitted from the organic light-emitting diode OLED. As an example, the size and/or width of the opening 117OP may correspond to the size and/or width of the emission area EA. Accordingly, the size and/or width of the sub-pixel PX may depend on the size and/or width of the opening 117OP of the bank layer 117.

The intermediate layer 220 may include an emission layer 222 formed to correspond to the sub-pixel electrode 210. The emission layer 222 may include a polymer organic material or a low-molecular weight organic material emitting light having a preset color. The emission layer 222 may include an inorganic emission material or quantum dots. The sub-pixel PX may be configured to emit red, blue, green, or white light depending on a color of light emitted by the emission layer 222.

In an embodiment, the intermediate layer 220 may include a first functional layer 221 and a second functional layer 223 respectively disposed under and on the emission layer 222. The first functional layer 221 may include, for example, a hole transport layer (HTL), or include an HTL and a hole injection layer (HIL). The second functional layer 223 may be an element disposed on the emission layer 222 and may include an electron transport layer (ETL) and/or an electron injection layer (EIL). Like the common electrode 230 described below, the first functional layer 221 and/or the second functional layer 223 may be common layers covering (or overlapping) the substrate 100 entirely.

The common electrode 230 may be disposed on the sub-pixel electrode 210 and may overlap the sub-pixel electrode 210. The common electrode 230 may include a conductive material having a low work function. As an example, the common electrode 230 may include a (semi) transparent layer including silver (Ag), magnesium (Mg), aluminum (Al), platinum (Pt), palladium (Pd), gold (Au), nickel (Ni), neodymium (Nd), iridium (Ir), chrome (Cr), an alloy thereof, or a combination thereof. The common electrode 230 may further include a layer on the (semi) transparent layer, the layer including ITO, IZO, ZnO, or In₂O₃, or a combination thereof. The common electrode 230 may be formed as a body (e.g., single body) to cover (or overlap) the substrate 100 entirely.

The encapsulation layer 300 may be disposed on the display element layer DEL and may cover (or overlap) the display element layer DEL. The encapsulation layer 300 may include at least one inorganic encapsulation layer and at least one organic encapsulation layer. In an embodiment. In an embodiment, it is shown in FIG. 11 that the encapsulation layer 300 includes a first inorganic encapsulation layer 310, an organic encapsulation layer 320, and a second inorganic encapsulation layer 330 that are sequentially stacked on each other.

The first inorganic encapsulation layer 310 and the second inorganic encapsulation layer 330 may include at least one inorganic material from among aluminum oxide, titanium oxide, tantalum oxide, hafnium oxide, zinc oxide, silicon oxide, silicon nitride, and silicon oxynitride. The organic encapsulation layer 320 may include a polymer-based material. The polymer-based material may include an acryl-based resin, an epoxy-based resin, polyimide, polyethylene, or a combination thereof. In an embodiment, the organic encapsulation layer 320 may include acrylate. The organic encapsulation layer 320 may be formed by curing a monomer or coating a polymer. The organic encapsulation layer 320 may be transparent.

Although not shown, a touch sensor layer may be disposed on the encapsulation layer 300. An optical functional layer may be disposed on the touch sensor layer. The touch sensor layer may obtain coordinate information corresponding to an external input, for example, a touch event. The optical functional layer may be configured to reduce the reflectivity of light (external light) incident toward the display panel from outside, and/or improve the color purity of light emitted from the display panel. In an embodiment, the optical functional layer may include a phase retarder and/or a polarizer. The phase retarder may include a film-type retarder or a liquid crystal coated-type retarder. The phase retarder may include a λ/2 phase retarder and/or a λ/4 phase retarder. The polarizer may include a film-type polarizer or a liquid crystal coated-type polarizer. The film-type polarizing layer may include a stretchable synthetic resin film, and the liquid crystal coated-type polarizing layer may include liquid crystals arranged in an arrangement. Each of the retarder and the polarizer may further include a protective film.

An adhesive member may be disposed between the touch sensor layer and the optical functional layer. For the adhesive member, a general member in the art may be employed without limitation.

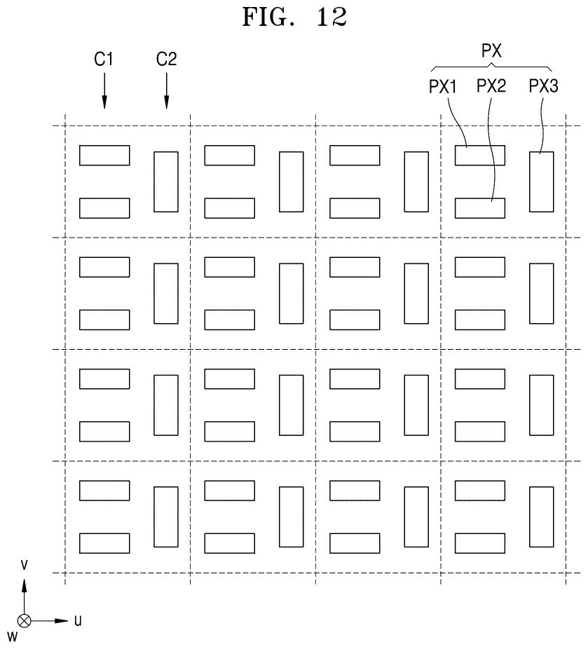

FIG. 12 is a schematic plan view of a sub-pixel arrangement of the display panel 1 according to an embodiment.

Referring to FIG. 12, the display area DA may include multiple sub-pixels PX. The sub-pixels PX may be disposed two-dimensionally in the first direction (u direction) and the second direction (v direction). In an embodiment, the first direction (u direction) may correspond to the movement direction (e.g., x direction of FIG. 1) of the deposition source 50, and the second direction (v direction) may correspond to the nozzle direction (e.g., y direction of FIG. 1) of the deposition source 50. The third direction (w direction) may correspond to a −z direction of FIG. 1.

The sub-pixels PX may include a first sub-pixel PX1 of a first color, a second sub-pixel PX2 of a second color, and a third sub-pixel PX3 of a third color. In an embodiment, for example, the first sub-pixel PX1 may be a green sub-pixel emitting green light, the second sub-pixel PX2 may be a red sub-pixel emitting red light, and the third sub-pixel PX3 may be a blue sub-pixel emitting blue light. Hereinafter, description is made on the assumption that the first sub-pixel PX1 is a green sub-pixel, the second sub-pixel PX2 is a red sub-pixel, and the third sub-pixel PX3 is a blue sub-pixel. It is shown in FIG. 12 that the first sub-pixel PX1, the second sub-pixel PX2, and the third sub-pixel PX3 configure a pixel as a minimum unit repeated for displaying. The pixel as a minimum unit may be provided in plural, and repeatedly arranged in the first direction (e.g., u direction) and the second direction (e.g., v direction).

The first pixel PX1 and the second pixel PX2 may be alternately disposed in a first column C1, and the third pixel PX3 may be disposed in a second column C2 adjacent to the first column C1. Two of the first sub-pixel PX1, the second sub-pixel PX2, and the third sub-pixel PX3 may be arranged to correspond to the remaining one. As an example, the third sub-pixel PX3 may be arranged to correspond to the first sub-pixel PX1 and the second sub-pixel PX2 in the first direction (e.g., u direction).

The first sub-pixel PX1, the second sub-pixel PX2, and the third sub-pixel PX3 may each have a quadrangular shape in a plan view. Here, the quadrangle may include a quadrangle with round vertexes. However, the embodiment is not necessarily limited thereto. In an embodiment, the first sub-pixel PX1, the second sub-pixel PX2, and the third sub-pixel PX3 may each have a polygonal shape other than a circular shape, an elliptical shape, or a quadrangular shape in a plan view. Here, the polygon may include a polygon with round vertexes.

In an embodiment, the first sub-pixel PX1, the second sub-pixel PX2, and the third sub-pixel PX3 may have a rectangular shape having first sides extending in the first direction (e.g., u direction) and second sides extending in the second direction (e.g., v direction) in a plan view. As an example, the first sub-pixel PX1 and the second sub-pixel PX2 may have a rectangular shape in which first sides thereof are greater than second sides thereof. The third sub-pixel PX3 may have a rectangular shape in which second sides thereof are greater than first sides thereof. A length of the second side of the third sub-pixel PX3 may be greater than a sum of the second side of the first sub-pixel PX1 and the second side of the second sub-pixel PX2.

At least some of the first sub-pixel PX1, the second sub-pixel PX2, and the third sub-pixel PX3 may have different sizes. In an embodiment, a size of the third sub-pixel PX3 may be greater than a size of the first sub-pixel PX1 and a size of the second sub-pixel PX2. As an example, a size of the third sub-pixel PX3 may be greater than a size of the first sub-pixel PX1, and a size of the first sub-pixel PX1 may be greater than the second sub-pixel PX2. However, the disclosure is not necessarily limited thereto. In an embodiment, a size of the third sub-pixel PX3 may be greater than a size of the first sub-pixel PX1, and a size of the second sub-pixel PX2 may be greater than the first sub-pixel PX1.

Here, the size of the sub-pixel PX may denote a planar size of the emission area EA (see FIG. 11) of the display element (e.g., the organic light-emitting diode OLED of FIG. 11) implementing each sub-pixel PX. The size of the emission area EA (see FIG. 11) may be defined by the opening 117OP (see FIG. 11) defined in the bank layer 117 (see FIG. 11).

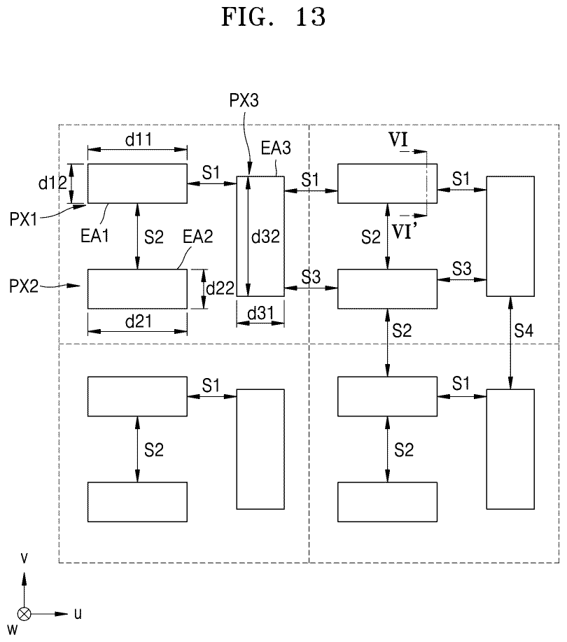

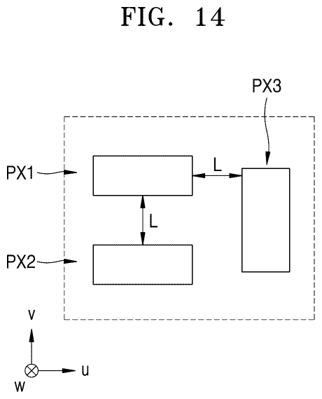

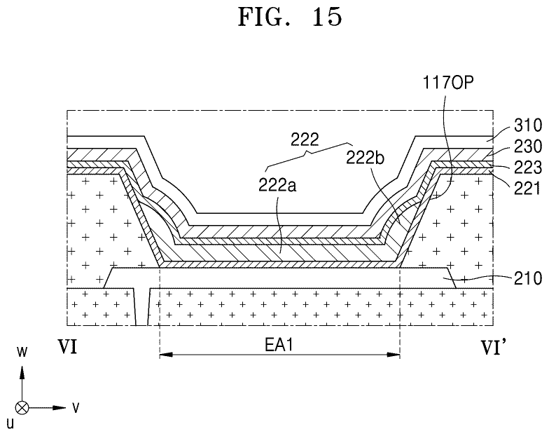

FIG. 13 is an arrangement view showing an arrangement of sub-pixels of the display panel 1 according to an embodiment, and FIG. 14 is an arrangement view showing an arrangement of sub-pixels of a display panel according to a comparative example. FIG. 15 is a schematic cross-sectional view of the display panel 1, taken along line VI-VI′ of FIG. 13 according to an embodiment. Sub-pixels of FIG. 13 may have an arrangement structure of sub-pixels of FIG. 12.

Referring to FIG. 13, in a pixel (e.g., single pixel), the first sub-pixel PX1 and the third sub-pixel PX3 may be arranged in the first direction (e.g., u direction), the second sub-pixel PX2 and the third sub-pixel PX3 may be arranged in the first direction (e.g., u direction), and the first sub-pixel PX1 and the second sub-pixel PX2 may be arranged in the second direction (e.g., v direction). The first direction (u direction) may correspond to the movement direction (e.g., x direction of FIG. 1) of the deposition source 50, and the second direction (v direction) may correspond to the nozzle direction (e.g., y direction of FIG. 1) of the deposition source 50.

In a plan view, a separation distance S1 between the first sub-pixel PX1 and the third sub-pixel PX3 adjacent to each other may be different from a separation distance S2 between the first sub-pixel PX1 and the second sub-pixel PX2 adjacent to each other. The separation distance S1 between the first sub-pixel PX1 and the third sub-pixel PX3 adjacent to each other may be less than the separation distance S2 between the first sub-pixel PX1 and the second sub-pixel PX2 adjacent to each other.

Similarly, a separation distance S3 between the second sub-pixel PX2 and the third sub-pixel PX3 adjacent to each other may be different from the separation distance S2 between the first sub-pixel PX1 and the second sub-pixel PX2 adjacent to each other. A separation distance S3 between the second sub-pixel PX2 and the third sub-pixel PX3 adjacent to each other may be less than the separation distance S2 between the first sub-pixel PX1 and the second sub-pixel PX2 adjacent to each other.

Here, a separation distance between the sub-pixels PX may denote a separation distance between the emission areas EA of the sub-pixels PX. For example, a separation distance between the sub-pixels PX may denote a planar separation distance between the openings 117OP (see FIG. 11) of the bank layer 117 (see FIG. 11) respectively corresponding to the sub-pixels PX. As an example, a separation distance between the first sub-pixel PX1 and the second sub-pixel PX2 may denote a separation distance between a first emission area EA1 of the first sub-pixel PX1 and a second emission area EA2 of the second sub-pixel PX2. A separation distance between the second sub-pixel PX2 and the third sub-pixel PX3 may denote a separation distance between a second emission area EA2 of the second sub-pixel PX2 and a third emission area EA3 of the third sub-pixel PX3. A separation distance between the first sub-pixel PX1 and the third sub-pixel PX3 may denote a separation distance between the first emission area EA1 of the first sub-pixel PX1 and the third emission area EA3 of the third sub-pixel PX3.

The separation distance S1 between the first sub-pixel PX1 and the third sub-pixel PX3 in a pixel may be substantially equal to a separation distance between the first sub-pixel PX1 and the third sub-pixel PX3 adjacent to each other in the first direction (e.g., u direction) and included in different pixels, respectively.

The separation distance S3 between the second sub-pixel PX2 and the third sub-pixel PX3 in a pixel may be substantially equal to a separation distance between the second sub-pixel PX2 and the third sub-pixel PX3 adjacent to each other in the first direction (e.g., u direction) and included in different pixels, respectively.

The separation distance S1 between the first sub-pixel PX1 and the second sub-pixel PX2 in a pixel may be substantially equal to a separation distance between the first sub-pixel PX1 and the second sub-pixel PX2 adjacent to each other in the second direction (e.g., v direction) and included in different pixels, respectively.

A separation distance S4 between the third sub-pixels PX3 adjacent to each other may be greater than the separation distance S2 between the first sub-pixel PX1 and the second sub-pixel PX2 adjacent to each other.

The separation distance S1 between the first sub-pixel PX1 and the third sub-pixel PX3 adjacent to each other may be substantially equal to the separation distance S3 between the second sub-pixel PX2 and the third sub-pixel PX3 adjacent to each other.

In an embodiment, a length d11 of a first side of the first sub-pixel PX1 may be greater than a length d12 of a second side. A length d21 of a first side of the second sub-pixel PX2 may be greater than a length d22 of a second side. A length d31 of a first side of the third sub-pixel PX3 may be less than a length d32 of a second side. The length d32 of the second side of the third sub-pixel PX3 may be greater than or substantially equal to a sum of the length d12 of the second side of the first sub-pixel PX1 and the length d22 of the second side of the second sub-pixel PX2. The length d31 of the first side of the third sub-pixel PX3 may be less than the length d21 of the first side of the second sub-pixel PX2 and the length d11 of the first side of the first sub-pixel PX1. In an embodiment, the length d11 of the first side of the first sub-pixel PX1 may be substantially equal to the length d21 of the first side of the second sub-pixel PX2.

The emission layer 222 (see FIG. 11) of each of the first sub-pixel PX1, the second sub-pixel PX2, and the third sub-pixel PX3 having the planar arrangement structure may be formed during a deposition process by the apparatus 2 for manufacturing the display apparatus described with reference to FIGS. 1 to 6. As an example, during an operation in which the deposition source sprays the deposition material while moving in a direction (e.g., single direction) relative to the substrate and the mask assembly, the emission layer 222 of each of the first sub-pixel PX1, the second sub-pixel PX2, and the third sub-pixel PX3 may be formed. The first sub-pixel PX1, the second sub-pixel PX2, and the third sub-pixel PX3 may be formed using different deposition materials.

As described with reference to FIGS. 5 to 6B, during the process of depositing the emission layer 222 of each of the first sub-pixel PX1, the second sub-pixel PX2, and the third sub-pixel PX3, a shadow region may be more pronounced in the nozzle direction (e.g., v direction of FIG. 13) of the deposition source than the movement direction (e.g., u direction of FIG. 13) of the deposition source.

However, in an embodiment, separation distances between the sub-pixels PX may be designed differently in the movement direction (e.g., u direction) of the deposition source and the nozzle direction (e.g., v direction) of the deposition source in which the shadow region appears more pronounced. A separation distance between the sub-pixels PX may be designed based on a case where, as a comparative example shown in FIG. 14, a separation distance between the first sub-pixel PX1 and the third sub-pixel PX3 and a separation distance between the first sub-pixel PX1 and the second sub-pixel PX2 are substantially equal to L. While reducing a length of a second side of the first sub-pixel PX1 and a length of a second side of the second sub-pixel PX2 arranged in the nozzle direction (e.g., v direction) of the deposition source, a separation distance between the first sub-pixel PX1 and the second sub-pixel PX2 arranged in the nozzle direction (e.g., v direction) of the deposition source may be increased. To keep an area of each of the first sub-pixel PX1 and the second sub-pixel PX2 as equal as possible, while increasing a length of a first side of the first sub-pixel PX1 and a length of a first side of the second sub-pixel PX2, a separation distance between the first sub-pixel PX1 and the third sub-pixel PX3 and/or a separation distance between the second sub-pixel PX2 and the third sub-pixel PX3 arranged in the movement direction (e.g., u direction) of the deposition source may be reduced.

The emission layer 222 of the sub-pixel PX may be formed in the opening 117OP of the bank layer 117. The emission layer 222 needs to be uniformly formed to a normal thickness in the opening 117OP of the bank layer 117. As described above, the planar shape of the sub-pixel PX may be the same as the planar shape of the opening 117OP of the bank layer 117 defining the emission area EA of the sub-pixel PX. Accordingly, because, in case that a length of a second side of each of the first sub-pixel PX1 and the second sub-pixel PX2 arranged in the nozzle direction (e.g., v direction) of the deposition source is reduced, an area of the opening 117OP of each of the first sub-pixel PX1 and the second sub-pixel PX2 in which the emission layer 222 needs to be deposited to a normal thickness in the nozzle direction (e.g., v direction) of the deposition source is reduced, the inner shadow region may be also reduced.

Accordingly, according to the disclosure, because a separation distance between the first sub-pixel PX1 and the third sub-pixel PX3 in the movement direction (e.g., u direction) of the deposition source, and a separation distance between the first sub-pixel PX1 and the second sub-pixel PX2 in the nozzle direction (e.g., v direction) of the deposition source are designed different from each other, deposition uniformity in the movement direction (e.g., u direction) of the deposition source and the nozzle direction (e.g., v direction) of the deposition source may be improved. Accordingly, a spot defect of the display panel due to magnetic force patterns may be reduced.

Compared to a case where a separation distance between the first sub-pixel PX1 and the third sub-pixel PX3 according to a comparative example and a separation distance between the first sub-pixel PX1 and the second sub-pixel PX2 are equal to L, a separation distance S2 between the first sub-pixel PX1 and the second sub-pixel PX2 arranged in the nozzle direction (e.g., v direction) of the deposition source may be L+X1 that extends by X1. X1 may satisfy Equation 1 below.

$$X 1 = ( arctangent ( α 1 ) - arctangent ( α2 ) ) \times ( t 1 + t 2 ) \qquad [ Equation 1 ]$$

Here, α1 is a minimum incident angle of the deposition material incident to the display substrate DS in the nozzle direction (e.g., v direction of FIG. 13) of the deposition source 50, α2 is a minimum incident angle of the deposition material incident to the display substrate DS in the movement direction (e.g., u direction of FIG. 13) of the deposition source 50, t1 is a separation distance between the mask sheet 42 and the display substrate DS, and t2 may denote a vertical distance from a surface (e.g., single surface facing a +z direction of FIG. 3B) of the mask sheet 42 facing the display substrate DS to the protrusion TP.

In an embodiment, L may be in a range of about 15 μm to about 30 μm.

In an embodiment, X1 may be in a range of about 0.5 μm to about 3 μm. Preferably, X1 may be in a range of about 0.5 μm to about 2 μm.

Compared to a case where a separation distance between the first sub-pixel PX1 and the third sub-pixel PX3 according to a comparative example and a separation distance between the first sub-pixel PX1 and the second sub-pixel PX2 are equal to L, a separation distance S1 between the first sub-pixel PX1 and the third sub-pixel PX3 arranged in the movement direction (e.g., u direction) of the deposition source may be L-X2 that is reduced by X2. X2 may be designed as a numerical value that supplements the area of the emission area of each of the first sub-pixel PX1 and the second sub-pixel PX2. As an example, in case that a length of a second side of each of the first sub-pixel PX1 and the second sub-pixel PX2 arranged in the nozzle direction (e.g., v direction) of the deposition source is reduced, a length of the first side of each of the first sub-pixel PX1 and the second sub-pixel PX2 may increase to supplement the areas of the first sub-pixel PX1 and the second sub-pixel PX2 as much as possible. A separation distance between the first sub-pixel PX1 and the third sub-pixel PX3 arranged in the movement direction (e.g., u direction) of the deposition source may be reduced by taking into account the increased length of the first side of the first sub-pixel PX1.

In an embodiment, X2 may be 2 μm or less. Preferably, X2 may be in a range of about 0.5 μm to about 2 μm. More preferably, X2 may be in a range of about 0.5 μm to about 1 μm. Because X2 is a reduced value of a separation distance between the sub-pixels, for example, the first sub-pixel PX1 and the third sub-pixel PX3, X2 may denote reduction in a process margin. In case that X2 is greater than about 2 μm, a defect due to a process error may increase while the emission layer and the like of the sub-pixel is deposited.

In an embodiment, a separation distance S2 between the first sub-pixel PX1 and the second sub-pixel PX2 may be in a range of about 15.5 μm to about 32 μm.

In an embodiment, a separation distance S1 between the first sub-pixel PX1 and the third sub-pixel PX3 may be in a range of about 14.5 μm to about 28 μm. Preferably,

FIG. 15 shows, as an example, a schematic cross-section of the first sub-pixel PX1 in the nozzle direction (e.g., v direction) of the deposition source, showing, for convenience of description, a display element of the first sub-pixel PX1.

Referring to FIG. 15, the emission layer 222 of the first sub-pixel PX1 may be formed in the opening 117OP of the bank layer 117 defining the first emission area EA1. The emission layer 222 of the first sub-pixel PX1 may include a first portion 222a and a second portion 222b, and the first portion 222a may be in contact with the sub-pixel electrode 210 exposed by the opening 117OP of the bank layer 117, and the second portion 222b extends in a lateral direction from the first portion 222a and is in contact with the bank layer 117.

In an embodiment, a thickness of the first portion 222a of the emission layer 222 of the first sub-pixel PX1 may be uniformly formed. A thickness of the second portion 222b of the emission layer 222 of the first sub-pixel PX1 may not be uniform. As an example, the second portion 222b of the emission layer 222 of the first sub-pixel PX1 may have a reduced thickness toward an outer portion thereof. However, the disclosure is not necessarily limited thereto. In an embodiment, the first sub-pixel PX1 may be formed to a unform thickness over the entire emission layer 222 including the first portion 222a and the second portion 222b. Likewise, although not shown in FIG. 15, the emission layer 222 of each of the second sub-pixel PX2 and the third sub-pixel PX3 may be formed to a uniform thickness in a region that is in contact with the sub-pixel electrode 210 and exposed by the opening 117OP of the bank layer 117.

Here, the thickness of the emission layer 222 may denote a vertical distance between a surface (e.g., single surface) where the emission layer 222 is in contact with a lower layer thereof (e.g., the first functional layer 221), and another surface located in the opposite direction of the lower layer.

In case the emission layer 222 has a uniform thickness, it may mean a case where the same thickness is measured regardless of a point at which the emission layer 222 is measured. In case that the emission layer 222 has a uniform thickness, it may mean a case where the thickness is measured within an error range of about 5%. The emission layer 222 may have a uniform thickness within a range of about 5%.

According to an embodiment, a display panel with reduced spot defects caused by brightness difference, a method of manufacturing the display panel, and an electronic apparatus including the display panel may be implemented. However, the scope of the disclosure is not limited by this effect.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A display panel comprising:
a first sub-pixel, a second sub-pixel, and a third sub-pixel that emits light of different colors, wherein
the first sub-pixel and the third sub-pixel are arranged in a first direction in a plan view,
the first sub-pixel and the second sub-pixel are arranged in a second direction perpendicular to the first direction in a plan view, and
a separation distance between the first sub-pixel and the third sub-pixel is different from a separation distance between the first sub-pixel and the second sub-pixel.

2. The display panel of claim 1, wherein the separation distance between the first sub-pixel and the third sub-pixel in a plan view is less than the separation distance between the first sub-pixel and the second sub-pixel.

3. The display panel of claim 1, wherein the separation distance between the first sub-pixel and the second sub-pixel in a plan view is in a range of about 15.5 μm to about 32 μm.

4. The display panel of claim 1, wherein each of the first sub-pixel, the second sub-pixel, and the third sub-pixel has a rectangular shape in a plan view with a first side extending in the first direction and a second side extending in the second direction.

5. The display panel of claim 4, wherein
a length of the first side of the first sub-pixel is substantially equal to a length of the first side of the second sub-pixel, and
a length of the second side of the first sub-pixel is different from a length of the second side of the second sub-pixel.

6. The display panel of claim 4, wherein
a length of the first side of the first sub-pixel is greater than a length of the second side of the first sub-pixel,
a length of the first side of the second sub-pixel is greater than a length of the second side of the second sub-pixel, and
a length of the first side of the third sub-pixel is less than a length of the second side of the third sub-pixel.

7. The display panel of claim 1, wherein the third sub-pixel corresponds to the first sub-pixel and the second sub-pixel in the first direction.

8. The display panel of claim 1, wherein
an area of the first sub-pixel is greater than an area of the second sub-pixel, and
an area of the third sub-pixel is greater than an area of the first sub-pixel.

9. The display panel of claim 1, wherein
each of the first sub-pixel, the second sub-pixel, and the third sub-pixel includes:
a sub-pixel electrode;
an emission layer disposed on the sub-pixel electrode; and
an opposite electrode disposed on the emission layer,
each of the first sub-pixel, the second sub-pixel, and the third sub-pixel is defined by an opening in a bank layer disposed on the sub-pixel electrode,
the bank layer overlaps edge portions of the sub-pixel electrode, and
the emission layer of the first sub-pixel has a uniform thickness in a region in which the emission layer is in contact with the sub-pixel electrode exposed by the opening of the bank layer.

10. A method of manufacturing a display panel, comprising:
providing the display panel that includes a first sub-pixel, a second sub-pixel, and a third sub-pixel;
disposing a substrate and a mask assembly inside a chamber, the mask assembly includes a mask sheet; and
spraying a deposition material onto the substrate while moving a deposition source in a first direction relative to the substrate, wherein
the first sub-pixel and the third sub-pixel are arranged in the first direction,
the first sub-pixel and the second sub-pixel are arranged in a second direction perpendicular to the first direction, and
a separation distance between the first sub-pixel and the third sub-pixel is different from a separation distance between the first sub-pixel and the second sub-pixel in a plan view.

11. The method of claim 10, wherein
the deposition source includes a plurality of nozzles arranged in the second direction, and
at least some of the plurality of nozzles are tilted at a preset angle.

12. The method of claim 10, wherein
each of the first sub-pixel, the second sub-pixel, and the third sub-pixel includes:
a sub-pixel electrode;
an emission layer; and
an opposite electrode, and
the spraying of the deposition material includes forming the emission layer of each of the first sub-pixel, the second sub-pixel, and the third sub-pixel.

13. The method of claim 10, wherein the separation distance between the first sub-pixel and the third sub-pixel in a plan view is less than the separation distance between the first sub-pixel and the second sub-pixel.

14. The method of claim 10, wherein, the separation distance between the first sub-pixel and the second sub-pixel in a plan view is in a range of about 15.5 μm to about 32μ m.

15. The method of claim 10, wherein each of the first sub-pixel, the second sub-pixel, and the third sub-pixel has a rectangular shape in a plan view with a first side extending in the first direction and a second side extending in the second direction.

16. The method of claim 15, wherein
a length of the first side of the first sub-pixel is substantially equal to a length of the first side of the second sub-pixel, and
a length of the second side of the first sub-pixel is different from a length of the second side of the second sub-pixel.

17. The method of claim 15, wherein
a length of the first side of the first sub-pixel is greater than a length of the second side of the first sub-pixel,
a length of the first side of the second sub-pixel is greater than a length of the second side of the second sub-pixel, and
a length of the first side of the third sub-pixel is less than a length of the second side of the third sub-pixel.

18. The method of claim 10, wherein the third sub-pixel corresponds to the first sub-pixel and the second sub-pixel in the first direction.

19. A display panel manufactured by the method of claim 10.

20. An electronic apparatus comprising:
the display panel of claim 19; and
a lower cover forming an exterior of the electronic apparatus and having an opening exposing a portion of the display panel.
